(19) United States
(12) Patent Application Publication
(10) Pub. No.: US 2014/0332076 A1
(43) Pub. Date: Nov. 13, 2014

(54) SYSTEMS AND METHODS USING METAL NANOSTRUCTURES IN SPECTRALLY SELECTIVE ABSORBERS

(71) Applicants: Jifeng Liu, Hanover, NH (US); Xiaoxin Wang, Hanover, NH (US); Xiaobai Yu, West Lebanon, NH (US)

(72) Inventors: Jifeng Liu, Hanover, NH (US); Xiaoxin Wang, Hanover, NH (US); Xiaobai Yu, West Lebanon, NH (US)

(21) Appl. No.: 14/340,608

(22) Filed: Jul. 25, 2014

Related U.S. Application Data
(63) Continuation-in-part of application No. 13/736,058, filed on Jan. 7, 2013.
(60) Provisional application No. 61/858,492, filed on Jul. 25, 2013.
(60) Provisional application No. 62/020,969, filed on Jul. 3, 2014.
(60) Provisional application No. 61/583,585, filed on Jan. 5, 2012.

(51) Int. Cl. G02B 5/22; B05D 1/00; B05D 3/02; H01L 31/052

(52) U.S. Cl. CPC G02B 5/22; H01L 31/0527; B05D 1/005; B05D 3/0254; B82Y 20/00
USPC 136/259; 427/372.2; 427/397.7; 359/360; 977/773

(57) ABSTRACT

Solution-processed Ni nanochain-SiOₓ (x<2) and Ni nanochain-SiO₂ selective solar thermal absorbers that exhibit a strong anti-oxidation behavior up to 600° C. in air. The thermal stability is far superior to Ni nanoparticle-Al₂O₃ selective solar thermal absorbers. The SiOₓ (x<2) and SiO₂ matrices are derived from hydrogen silsesquioxane (HSQ) and tetraethyl orthosilicate (TEOS) precursors, respectively. We find that both the excess Si and the stoichiometric SiO₂ matrix contribute to antioxidation behavior. Methods of making the selective solar thermal absorbers are described. A system, and method of manufacture of the system, for spectrally selective radiation absorption includes a matrix that includes metal nanostructures, each metal nanostructure having spectrally selective radiation absorption properties, such that the matrix reflects a majority of light incident thereupon for wavelengths greater than a cutoff wavelength and absorbs a majority of light incident thereupon for wavelengths smaller than the cutoff wavelength.

### CROSS-REFERENCE TO RELATED APPLICATIONS

This application is a continuation-in-part of co-pending U.S. patent application Ser. No. 13/736,058, filed Jan. 7, 2013, which application claimed priority to and the benefit of co-pending U.S. provisional patent application Ser. No. 61/583,585, filed on Jan. 5, 2012, and this application additionally claims priority to and the benefit of co-pending U.S. provisional patent application Ser. No. 61/858,492, filed Jul. 25, 2013, and co-pending U.S. provisional patent application Serial No. 62/020,969, filed Jul. 3, 2014, each of which applications is incorporated herein by reference in its entirety.

### STATEMENT REGARDING FEDERALLY FUNDED RESEARCH OR DEVELOPMENT

This invention was made with government support under Award No. 1315245 awarded by National Science Foundation's SBIR program. The government has certain rights in the invention.

### THE NAMES OF THE PARTIES TO A JOINT RESEARCH AGREEMENT

This invention resulted from work under a joint research agreement between Norwich Technologies, a Delaware Corporation, and Dartmouth College, a Nonprofit Corporation of Higher Education (103c) duly organized under the laws of the State of New Hampshire.

### FIELD OF THE INVENTION

The invention relates to absorbers of electromagnetic radiation in general and particularly to absorbers that are compatible with solar radiation.

### BACKGROUND OF THE INVENTION

Nanostructures are objects with at least one dimension on the nanoscale, generally 1-100 nanometers. Size wise, nanostructures bridge the gap between the quantum objects and bulk materials. A conventional bulk material has constant physical properties regardless of its size. In contrast, nanostructures often have size dependent properties resulting from a large fraction of atoms being located at the surface of the nanostructure, or otherwise related to their size. The small size and large surface-to-volume ratio of nanostructures allows for suspension of nanostructures in liquids.

Nanostructures have other unique properties due to their size scale being in the intermediate range between the pure quantum scale and the microscopic scale. Nanostructures exhibit quantum behavior and can be made to utilize these quantum effects. For example, some metal nanostructures have unusual spectral properties that are different from both those of a single atom or molecule and those of bulk materials. Light incident on a nanostructure may cause collective oscillation of electrons located on the nanostructure surface, an effect known as a surface plasmon. For metal nanostructures, incident light may couple with surface plasmons to create sustained electromagnetic waves, surface plasmon polaritons, propagating along the nanostructure surface. The properties of both surface plasmons and surface plasmon polaritons depend on the nanostructure composition, shape, and size. Hence, composition and size may be adjusted to tune the spectral properties of nanostructures in ways not possible for single atoms/molecules or bulk materials.

Nanostructures are used in some concentrated solar-thermal power (CSP) systems where sunlight is concentrated onto a light absorbing material, composed in part by nanostructures, that converts the electromagnetic energy to heat at high efficiency and transfers this heat to a thermal reservoir. In typical CSP systems, heat may be tapped from the reservoir to run steam, Stirling, or other heat engines, or for other purposes. In contrast to the electrical energy generated by photovoltaic systems, the thermal energy generated by concentrated solar power systems is easily stored as heat, thereby overcoming issues associated with sunlight being available only through parts of the day. A key component of a CSP system is a solar thermal absorber that efficiently absorbs sunlight, i.e., ultraviolet, visible, and near-infrared radiation, while emitting little thermal radiation, i.e., short-wavelength infrared and mid-infrared radiation, in order to avoid reemitting the harvested energy. In a prior system, this issue is addressed by embedding 5-10 nm sized metal nanoparticles in ceramic layers at different concentrations gradually decreasing with distance away from the thermal reservoir. The resulting refractive index profile allows sunlight to efficiently couple through to the thermal reservoir while thermal radiation from the reservoir is reflected. Oxidation of the metal nanoparticles is prevented by placing the absorber in a vacuum.

Prevention of metal oxidation at high temperatures has long been a significant challenge in materials science. Oxidation of metal nanostructures poses an even more significant issue because they have larger surface area and stronger reactivity, leading to easier and faster oxidation than bulk materials. Since metal nanostructures are more advantageous over conventional structures in many important applications, e.g. cermet solar selective absorber coatings for concentrated solar power (CSP) systems, oxidation prevention in metal nanostructures is of great significance. See for example Gordon J (2001), Solar Energy: the State of the Art (James & James Ltd, London) and Kennedy C E (2002), “Review of Mid- to High Temperature Solar Selective Absorber Materials”, National Renewable Energy Laboratory (NREL).

Selective solar thermal absorber coatings can convert solar energy efficiently into heat with minimal thermal radiation losses for CSP systems. Compared to photovoltaics, CSP can be more easily integrated with conventional power plants of larger scales and offers great advantages in low-cost energy storage since the heated working fluid (e.g. molten salt) can be stored and kept at a high temperature for an extended period of time. The latter is an attractive solution to the intermittency issue of solar energy. Most of the solar selective absorbers in CSP systems comprise metal nanoparticles embedded in a ceramic matrix, known as a “cermet”. See for example Carl M. Lampert, Coatings for enhanced photothermal energy collection, Solar Energy Materials 1 (1979) 319-341. Conventionally, the coating is designed as graded refractive index anti-reflection layers in the solar spectrum range, with the volume fraction of the metal nanoparticles gradually increasing from the surface to the coating/substrate interface. The size of metal nanoparticles is in the order of several nm, much smaller the wavelengths of interest. With adequate design of refractive indices profile and thicknesses of the cermet coating layers based on interference effect, low reflectance (high absorptance) in the solar spectral regime and high reflectance (low emittance) in the infrared thermal radiation regime can be achieved simultaneously. See for example P. Spinelli, M. Hebbink, R. de Waele, L. Black, F. Lenzmann, A. Polman, Optical impedance matching using coupled plasmonic nanoparticle arrays, Nano Letters 11 (2011) 1760-1765; Feng Cao, Kenneth McEnaney, Gang Chen, Zhifeng Ren, A review of cermet-based spectrally selective solar absorbers, Energy. Environment. Sci, DOI: 10.1039/c3ee43825b, (2014); and T. Bostrom, E. Wackelgard, G. Westin, Solution-chemical derived nickel-alumina coatings for thermal solar absorbers, Solar Energy 74 (2003) 497-503.

There are a couple of disadvantages for the conventional cermet absorbers, though: (1) the thicknesses of the layers need to be precisely controlled for optimal performance, which usually requires more costly vacuum depositions (See for example, N. Selvakumar, Harish C. Barshilia, Review of physical vapor deposited (PVD) spectrally selective coatings for mid- and high-temperature solar thermal applications, Solar Energy Materials and Solar Cells 98 (2012) 1-23); (2) The tiny size of the metal nanoparticles makes them highly susceptible to oxidation. Previous research reported that the enthalpy of Al nanoparticle oxidation decreases as the diameter of nanoparticle decreases. (See for example, K. Park, D. Lee, A. Rai, D. Mukherjee, and M. R. Zachariah, Size-Resolved Kinetic Measurements of Aluminum Nanoparticle Oxidation with Single Particle Mass Spectrometry, J. Phys. Chem. B 109 (2005) 7290-7299.) Therefore, most of the CPS receivers have to work under vacuum, which adds to additional cost. In addition, the vacuum breaching also became a major failure mechanism of CSP systems.

There is a need for improved solar absorbers that can operate at elevated temperatures in air.

### SUMMARY OF THE INVENTION

According to one aspect, the invention features a system for spectrally selective radiation absorption. The system comprises a matrix comprising uniformly dispersed metal nanostructures having plasmonic spectrally selective radiation absorption properties, such that the matrix reflects a majority of light incident thereupon for wavelengths greater than a cutoff wavelength and absorbs a majority of light incident thereupon for wavelengths smaller than the cutoff wavelength.

In one embodiment, the majority of light incident upon the metal nanostructures for wavelengths smaller than the cutoff wavelength is absorbed by surface plasmon resonance in the metal nanoparticles.

In another embodiment, each nanostructure comprises at least two metal nanoparticles, the at least two metal nanoparticles having a broader absorption spectrum than that of a single metal nanoparticle.

In yet another embodiment, the nanostructures comprise nanochains of metal nanoparticles. The nanochains could further form nano-network or nano-array structures.

In still another embodiment, the metal nanoparticles comprise a ferromagnetic metal or a transition metal.

In a further embodiment, the metal nanoparticles comprise Ni and the matrix comprises a selected one of SiOₓ (x<2) and SiO₂.

In yet a further embodiment, the spectrally selective radiation absorption properties of the metal nanostructures in the matrix are insensitive to the thickness of the matrix.

In an additional embodiment, the system further comprises a thermal reservoir

In one more embodiment, the cutoff wavelength is located between the peak of the solar radiation spectrum and the peak of the blackbody radiation spectrum of the thermal reservoir.

In still a further embodiment, the matrix is present in the form of a coating.

In one embodiment, the coating has a thickness in the range from the diameter of the metal nanoparticles to 10 μm. In some embodiments, the diameter of the metal nanoparticles range from 50 to 500 nm.

In another embodiment, the system further comprises a heat source and a photovoltaic element.

In yet another embodiment, the cutoff wavelength is located between the peak of the photovoltaic element absorption spectrum and the peak of the black body radiation spectrum of the heat source.

In still another embodiment, the matrix further comprises a material that forms chemical bonds with the metal nanoparticles such that the oxidation rate of the metal nanoparticles is reduced.

In a further embodiment, the material comprises at least one of Si, a Si—O network, Ge, a Ge—O network, a Si—C—O network, a Ge—C—O network, a Si—Ge—C—O network, or a combination thereof.

In another embodiment, the metal nanostructures comprise at least one metal nanoparticle containing a selected one of Ni, Cr, and Co.

In yet another embodiment, the at least one metal nanoparticle containing a selected one of Ni, Cr, and Co comprises a silicide.

According to another aspect, the invention relates to a method of manufacturing a spectrally selective absorber. The method comprises the steps of forming nanostructures, each nanostructure comprising at least one metal nanoparticle; uniformly dispersing the nanostructures in a matrix material to form a liquid matrix; applying the liquid matrix to a surface; drying the liquid matrix; and annealing the matrix.

In one embodiment, the matrix material forms chemical bonds with the metal nanoparticles such that the oxidation rate of the metal nanoparticles is reduced.

In another embodiment, the step of applying the liquid matrix is performed by solution-chemical processes.

In yet another embodiment, the solution-chemical processes comprise one or more of spin coating, drip coating, dip coating, spray coating, roller coating, and knife-over-edge coating.

In still another embodiment, the solution-chemical processes comprise spin coating at increasing spin rates comprising at least a lower spin rate and a higher spin rate.

In a further embodiment, the step of annealing is performed at increasing temperatures comprising at least a lower temperature and a higher temperature.

In yet a further embodiment, the step of forming nanostructures is performed by solution-chemical processes.

In an additional embodiment, the at least one metal nanoparticle comprises a selected one of Ni, Cr, and Co.

In yet another embodiment, the at least one metal nanoparticle comprising a selected one of Ni, Cr, and Co comprises a silicide.

In one more embodiment, the matrix material comprises at least one of SiOₓ (x<2), SiO₂, a precursor for SiOₓ (x<2), and a precursor for SiO₂.

In still a further embodiment, the matrix material comprises at least one of Si, a Si—O network, Ge, a Ge—O network, a Si—C—O network, a Ge—C—O network, a Si—Ge—C—O network, or a combination thereof.

In another embodiment, the surface is steel.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 illustrates one exemplary CSP system implemented with a metal nanostructure based, spectrally selective absorber, according to an embodiment.

FIG. 2 illustrates one exemplary spectrally selective absorber system based on metal nanostructures, according to an embodiment.

FIG. 3 illustrates one exemplary spectrally selective absorber system based on metal nanostructures in a matrix that reduces the metal oxidation rate, according to an embodiment.

FIG. 4 illustrates one exemplary method for manufacturing a metal nanostructure based, spectrally selective absorber system, according to an embodiment.

FIG. 5 illustrates calculated optical properties of one exemplary metal nanostructure based, spectrally selective absorber system for incident light polarized along the nanochain length, according to an embodiment.

FIG. 6 illustrates calculated optical properties of one exemplary, metal nanostructure based, spectrally selective, absorber system for incident light polarized perpendicular to the nanochain length, according to an embodiment.

FIG. 7 illustrates one exemplary method for manufacturing a metal nanostructure based, spectrally selective absorber, according to an embodiment.

FIG. 8 illustrates x-ray diffraction data of one exemplary metal nanostructure based, spectrally selective absorber system, according to an embodiment.

FIG. 9 illustrates optical spectra associated with one exemplary system using a metal nanostructure based, spectrally selective absorber, according to an embodiment.

FIG. 10 illustrates one exemplary method for manufacturing metal nanoparticles, according to an embodiment.

FIG. 11 illustrates one exemplary method for manufacturing metal nanoparticles, according to an embodiment.

FIG. 12 illustrates one exemplary method for manufacturing a metal nanostructure based, spectrally selective absorber system with antioxidation properties, according to an embodiment.

FIG. 13 illustrates oxidation rates for exemplary metal nanostructure based, spectrally selective absorber systems, according to embodiments.

FIG. 14 illustrates one exemplary thermophotovoltaic system implemented with a metal nanostructure based, spectrally selective emitter, according to an embodiment.

FIG. 15 illustrates one exemplary thermophotovoltaic system implemented with a metal nanostructure based, spectrally selective emitter, according to an embodiment.

FIG. 16A is a diagram of the chemical structure of HSQ in cage form.

FIG. 16B is a diagram of the chemical structure of HSQ in network form.

FIG. 17A is an image of a Ni nanochain suspension and powders.

FIG. 17B is a scanning electron microscopy (SEM) image of Ni nanochain-SiOₓ (x<2) cermet.

FIG. 18 is an X-ray diffraction (XRD) diagram showing data of Ni nanochain-SiOₓ (x<2) cermet coatings on Si substrate before and after annealing in N₂ at 750° C. for 20 min.

FIG. 19A is a plot of XRD data of Ni nanochain-SiOₓ (on Si) and Ni nanochain-Al₂O₃ coatings annealed in air at 450° C. for 15 min.

FIG. 19B is a plot of XRD data of Ni nanochain-SiOₓ coating on stainless steel substrate annealed in air at 500° C. for 20 min and 90 min. The XRD pattern shows practically no change, indicating that the oxidation process is retarded in the system.

FIG. 20A is a graph of XRD peak intensity ratio for NiO(200)/Ni(111) as a function of annealing time at different temperatures (450-600° C.) for Ni—SiOₓ, Ni—SiO₂ and Ni—Al₂O₃ systems. The extent of oxidation in Ni—SiOₓ is nearly 2 orders less than Ni—Al₂O₃, and 3-4× less than the Ni—SiO₂ system at 450° C. The vertical axis is in log scale.

FIG. 20B is a graph of XRD peak intensity ratio of NiO(200) to Ni(111), as a function of annealing time for Ni—HSQ vs. Ni—Al₂O₃ cermet coatings at different temperatures. Even after 600° C. annealing, the Ni—SiOₓ shows orders of magnitude less oxidation than Ni—Al₂O₃ annealed at 450° C. in air. The vertical axis is linear.

FIG. 21A is a graph of XRD peak ratio for NiO(200)/Ni(111) as a function of annealing time in Ni—SiOₓ (x<2) system at 450, 550 and 600° C. in air. The dashed lines show the fitting curves using Deal-Grove oxidation model. The solid line shows a fitting curve using phenomenological exponential association model for the case of 600° C. annealing.

FIG. 21B is a graph of XRD peak ratio for NiO(200)/Ni(111) as a function of annealing time. This graph shows the extent of oxidation as a function of annealing time for Ni—HSQ vs. Ni-TEOS cermet coatings. While TEOS is not as effective as HSQ in preventing oxidation, it still offers significantly better protection than Al₂O₃.

FIG. 22 is a graph showing an Arrhenius plot of NiO growth in Ni—SiOₓ system from 450° C. to 675° C. (or 723K to 948K). An Arrhenius fitting is given in the temperature range of 450-600° C. with an oxidation activation energy of Eₐ=0.87±0.17 eV. Remarkably, at >600° C. the oxidation rate drastically decreases from that at 600° C. and remains flat up to 675° C.

FIG. 23 is a graph showing FTIR spectra of (1) unannealed HSQ on Si substrate (2301); (2) Si substrate alone (2302); (3) Ni nanochain-SiOₓ (x<2) on Si annealed in N₂ at 750° C. (2303); and (4) Ni nanochain-SiOₓ (x<2) on Si annealed in N₂ at 750° C. followed by 600° C. in air (2304).

FIG. 24 is a graph showing X-ray photoelectron spectra (XPS) of (1) unannealed Ni—SiOₓ (x<2) on Si (2430); (2) Ni—SiOₓ (x<2) on Si annealed in N₂ at 750° C. (2420); and (3) Ni—SiOₓ (x<2) on Si annealed in N₂ at 750° C. and then in air up to 675° C. (2410). Silicide formation is clearly observed after annealing. The analysis shows that at the Ni—SiOₓ interface, the silicide is transformed from Ni₃Si to NiSi₂ as the temperature increases from 450° C. to 650° C., which offers more resistance to oxidation. This explains why the oxidation rate drops significantly at >600° C.

FIG. 25 is a graph showing a Raman spectrum of Ni—SiOₓ (x<2) on stainless steel substrate annealed at 750° C. in N₂ followed by 675° C. in air. Peaks corresponding to NiSi and NiSi₂ are clearly observed.

FIG. 26A is a graph showing absorptance/emittance spectra measured at room temperature (curves 2601-2603) and 300° C. (curve 2604). Curve 2601: stainless steel (SS) substrate alone; Curve 2602: as-coated Ni nanochain-SiOₓ on SS substrate; Curve 2603: Ni nanochain-SiOₓ on SS substrate annealed in air at 450° C. for 4 h; and Curve 2604: thermal emittance measured at 300° C. for Ni nanochain-SiOₓ on SS substrate annealed in air at 450° C. for 4 h. The data show a significant red-shift in the absorptance/emittance edge from λ˜1.0 to λ˜1.8 μm compared to room temperature, covering almost the entire solar spectrum regime.

FIG. 26B is a graph of the theoretically calculated optical response of Ni nanochain-SiOₓ (x<2) with (2611) and without (2612) Ni₃Si shells at room temperature using the methods in Xiaoxin Wang, Haofeng Li, Xiaobai Yu, Xiaoling Shi, Jifeng Liu, High-performance solution-processed plasmonic Ni nanochain-Al₂O₃ selective solar thermal absorbers, Applied Physics Letter 101 (2012) 203109. The extinction factor refers to the extinction cross-section divided by the cross-section of the Ni nanoparticles.

FIG. 27 is a graph showing the X-ray photoelectron (XPS) spectrum of Ni nanochain-HSQ annealed at 900° C. in N₂.

FIG. 28 is a graph showing the reflectance spectra measured at room temperature of Ni nanochain-HSQ on SS substrate after annealing at 450° C. for 4 h in air (2801) and after thermal cycling at 580° C. for 12 h in air (2802).

FIG. 29A is an image of a core-shell structure of Ni nanochain-HSQ annealed at 900° C. in N₂.

FIG. 29B is a TEM image of a Ni nanochain-HSQ annealed at 900° C. in N₂.

FIG. 30A, FIG. 30B, FIG. 30C, and FIG. 30D are TEM selected area electron diffraction (SAED) patterns of Ni nanochain-HSQ annealed at 900° C. in N₂.

### DETAILED DESCRIPTION

The present invention includes spectrally selective absorbers based on metal nanostructures. The spectrally selective absorbers disclosed herein have utility in CSP systems and as spectrally selective emitters in thermophotovoltaic systems. A discussion of CSP systems that use spectrally selective absorbers is described in U.S. Patent Application Publication No. US 2013/0220307 A1 (U.S. Ser. No. 13/736,058) published on Aug. 29, 2013, which application is incorporated herein by reference in its entirety. The metal nanostructures utilized have properties that enable simplified manufacturing of the spectrally selective absorbers compared to conventional nanoparticle based selective absorbers. The optical properties of the spectrally selective absorbers disclosed herein can be optimized for a given application by tuning physical properties of the metal nanostructures. In embodiments, the metal nanostructures are protected from oxidation by embedding the metal nanostructures in an antioxidation matrix. This offers further improvement over conventional solar absorbers by reducing need for absorbers to be kept under vacuum to prevent oxidation-induced degradation at the high temperatures. The spectrally selective absorbers in antioxidation matrix of the present invention may function in ambient atmosphere at temperatures relevant for CSP systems. These absorbers may be used in other applications where metal nanostructures are subject to oxidation.

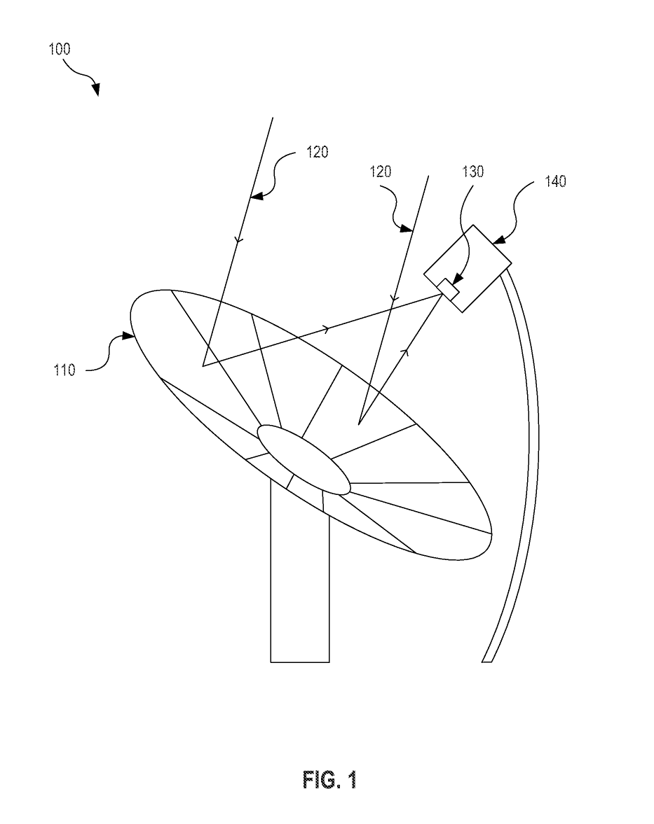

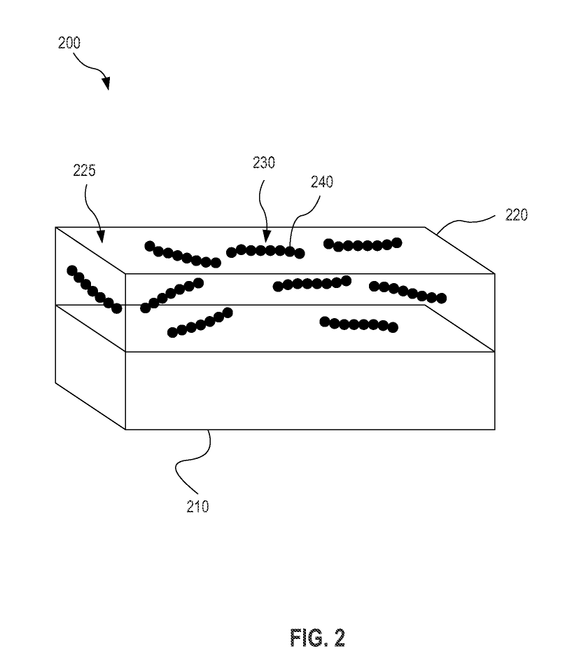

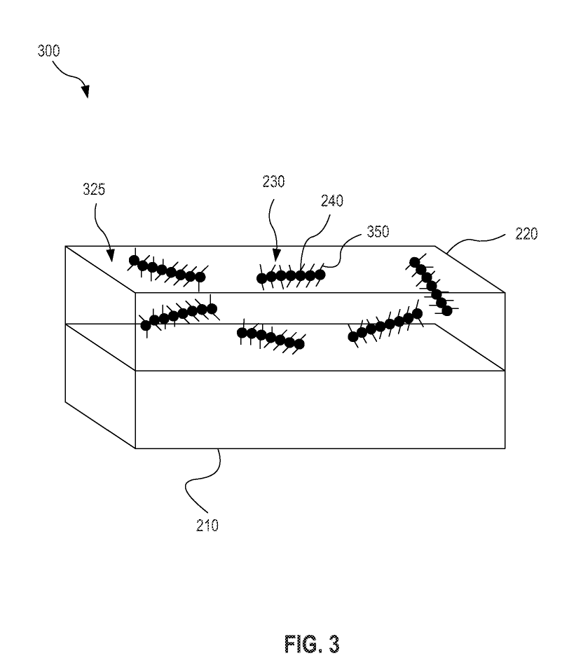

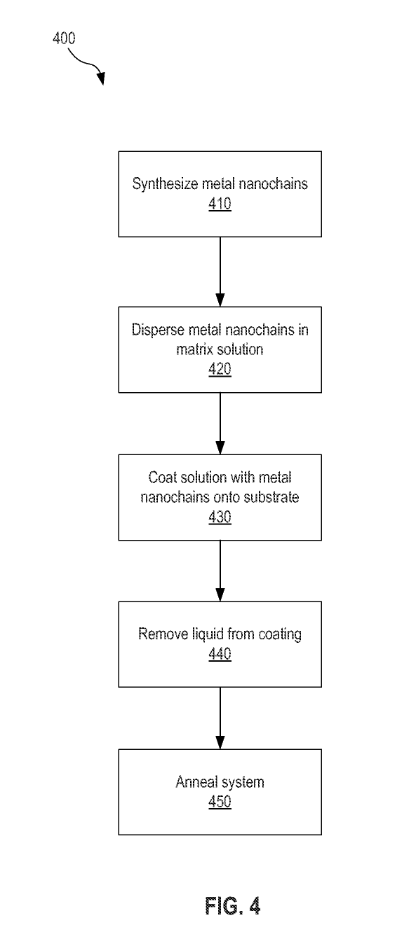

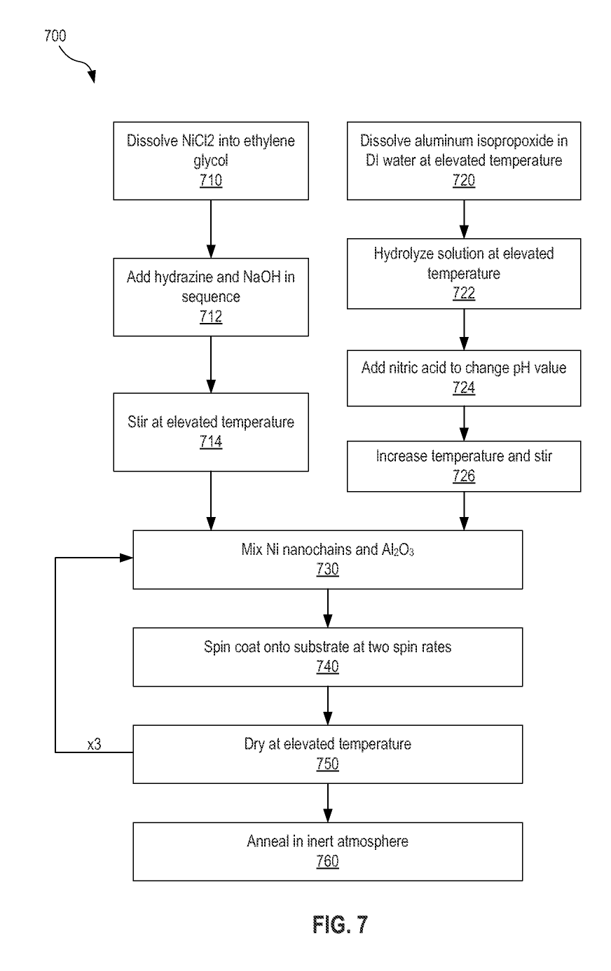

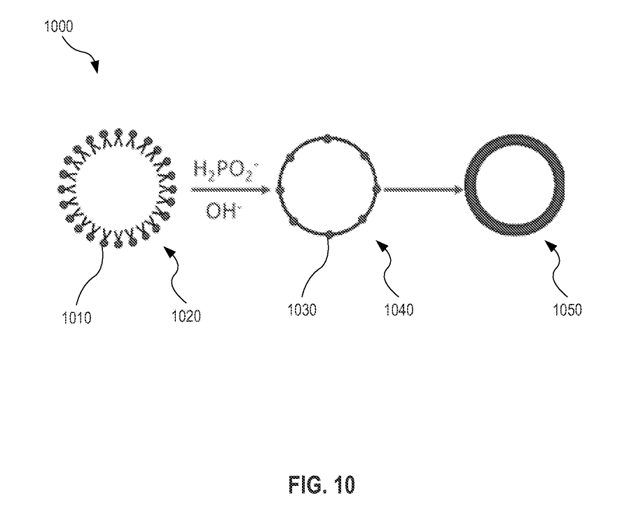

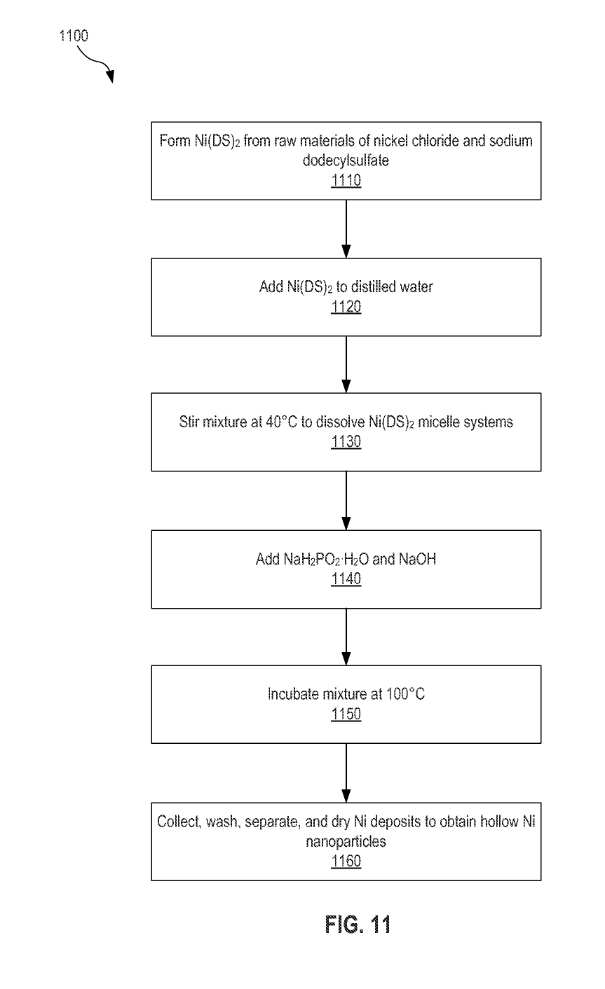

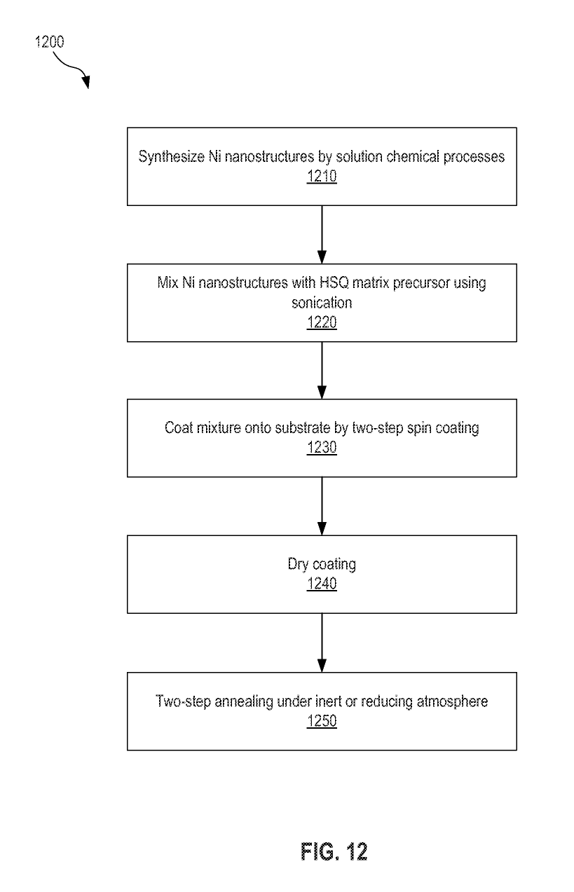

FIG. 1 is an illustration of a CSP system 100. CSP system 100 is of the Dish Stirling type and includes a parabolic reflector system 110 that reflects and concentrates incident sunlight exemplified by rays 120 onto a metal nanostructure based, spectrally selective absorber 130 according to the present invention. Absorber 130 is mounted in a receiver unit 140. In an embodiment, absorber 130 is absorber 200 of FIG. 2. In certain embodiments, absorber 130 is manufactured using one or more of the methods disclosed in method 400 (FIG. 4), method 700 (FIG. 7), method 1000 (FIG. 10), method 1100 (FIG. 11), and method 1200 (FIG. 12). In another embodiment, absorber 130 is antioxidation absorber 300 of FIG. 3. In particular embodiments, absorber 130 is a cermet having nanoparticles suspended in an oxidation-protective matrix manufactured using one or more of methods disclosed in method 400 (FIG. 4), method 1000 (FIG. 10), method 1100 (FIG. 11), and method 1200 (FIG. 12).

Conventional selective solar absorbers used in CSP systems consist of a substrate with a cermet composed by a series of layers coated thereupon, each layer containing specific concentration of metal nanoparticles with a diameter in the range 5-10 nm. The concentration of metal nanoparticles decreases with distance from the substrate, and both the cermet film thickness and the metal nanoparticle concentrations of each layer are tuned to provide optical impedance matching in the solar spectral regime but not in the infrared spectrum corresponding to thermal radiation. This concentration gradient provides spectral selectivity, which may be further enhanced by incorporating an infrared reflector between the cermet and the substrate. The cermet film thicknesses are critical for the optical performance, leading to stringent requirements to thickness control. Therefore, most existing cermet fabrication techniques rely on vacuum deposition such as sputtering, evaporation, of chemical vapor deposition. The present invention alleviates the stringent film thickness constraint of traditional cermet solar selective absorbers and facilitates solution-chemical processing.

FIG. 1 is to be interpreted in a non-limiting sense and spectrally selective absorber 130 can be incorporated into other types of CSP systems including, but not limited to, parabolic trough, Fresnel lens, reflector, and solar tower power systems.

FIG. 2 shows a metal-nanostructure based spectrally selective absorber 200. Absorber 200 includes a substrate 210 and a matrix 220 that contains metal nanochains 230 embedded in a matrix material 225, i.e., chains composed by metal nanoparticles 240 that may be solid or hollow. Not all metal nanochains and/or metal nanoparticles are labeled in FIG. 2. Unlike the nanoparticle-based cermet in conventional solar absorbers, the concentration of metal nanochains 230 is generally uniform throughout matrix 220. The spectral properties of matrix 220 are defined by the spectral properties of metal nanochains 230, which depends on a number of factors including, but not limited to, the size and composition of metal nanoparticles 240, the length of metal nanochains 230, and the shell thickness in the case of hollow nanoparticles 240.

In an embodiment, the diameter of metal nanoparticles 240 is chosen to meet two criteria: (a) Absorption and scattering in the solar spectrum is enhanced by optical excitation of surface plasmon polaritons, thereby increasing the absorption efficiency in the solar spectrum. (b) The longer wavelengths of thermal radiation is unable to resolve metal nanoparticles 240 and consequently, in the short-wavelength infrared and mid-infrared spectrum, matrix 220 functions as a continuous metal sheet and reflects thermal radiation from the CSP thermal reservoir back to the thermal reservoir. Meeting these two size criteria provides spectral selectivity, which may be further optimized as discussed in the following. The width of the absorption spectrum of metal nanochains 230 is influenced by the material composition of metal nanoparticles 240. In an embodiment, the surface plasmon polariton resonance is broadened by choosing a ferromagnetic material for nanoparticles 240 such as, iron, nickel, or cobalt. This increases the damping coefficient for the surface plasmon polaritons resulting in a broadened resonance better matched to the solar spectrum. For any given size and material composition of metal nanoparticles 240, the optical response of nanochains 230 may be further optimized by tailoring the length of metal nanochains 230.

Metal nanoparticles 240 may be solid or hollow. In an embodiment, metal nanoparticles 240 have a diameter in the range 50-400 nm. In another embodiment, the diameter of the metal nanoparticles range from 50 to 500 nm. In another embodiment, metal nanochains 230 are composed of 2-10,000 nanoparticles 240. Matrix material 225 may be a dielectric. In an embodiment, matrix 220 is a cermet. Cermets are characterized by high temperature resistance and are therefore well suited for CPS systems. In a further embodiment, metal nanoparticles 240 are composed of a ferromagnetic metal such as Iron (Fe), Nickel (Ni), or Cobalt (Co); a refractory metal (e.g., Tantalum, Tungsten, or Chromium); a metal with low oxidation properties such as Ni or Cr, or a combination thereof.

Examples of materials for substrate 210 include, but are not limited to, silicon, glass, or metal that can withstand the temperatures reached both in the CSP system and during manufacturing. In certain embodiments, substrate 210 is flexible and can be flexed to be in thermal contact with a non-planar thermal reservoir surface such as a working fluid tube of, for instance, a parabolic trough CSP system. In other embodiments, substrate 210 is the surface of a thermal reservoir, i.e., matrix 220 is applied directly onto the surface of the thermal reservoir. This has particular advantages for thermal reservoirs with non-planar surface geometries.

The spectral selectivity of absorber 200 is due to the intrinsic spectral properties of nanochains 230, as opposed to the cermet layer thicknesses of a conventional selective solar absorber. Hence, there are no stringent requirements to the thickness of matrix 220, which enables simpler and more cost-effective manufacturing methods than those associated with conventional selective solar absorbers. In an embodiment, matrix 220 is manufactured and applied to substrate 210 using solution-chemical processes. The thickness of matrix 220, measured in along the surface normal of substrate 210, is at least as great as the diameter of nanoparticles 240. There is no fundamental upper limit for the thickness of matrix 220. Its performance is insensitive to the thickness parameter as long as the thickness is sufficient to contain nanoparticles 240. In one embodiment, the thickness is chosen to enable simple and cost-effective manufacturing. For example, the thickness may range from the diameter of nanoparticles 240 (e.g., about 50-500 nm) up to about 10 μm. In another embodiment, the thickness is the minimum thickness. In this case, the thickness matches or is slightly greater than the diameter of nanoparticles 240, thereby minimizing the amount of material used to manufacture matrix 220.

Matrix material 220 can be any material suitable for a given application. For high-temperature applications such as CSP systems, suitable choices of matrix material 220 include, but are not limited to, aluminum oxide, aluminum nitride, silicon oxide, silicon oxynitride, or a combination thereof. In some embodiments, these matrix materials can be off-stoichiometry, for example, SiOₓ with x<2. In certain embodiments, matrix material is flexible such that absorber 200, post-manufacturing, can be shaped to come into good thermal contact with a non-planar surface.

Both conventional selective solar absorbers and the presently disclosed absorbers contain metals and the performance of the absorbers would be compromised if the metals were allowed to oxidize. Oxidation is particularly rapid at the high temperatures experienced in a CSP. In current CSP systems based on conventional selective solar absorbers, oxidation is prevented by keeping the cermets under vacuum. Vacuum breaching is, however, a major failure mechanism of current CSP systems, limiting the system lifetime as well as increasing fabrication cost. In an embodiment, metal nanoparticles 240 are composed of a metal with intrinsically low oxidation properties, for instance Ni. In another embodiment, the compositions of metal nanoparticles 240 and matrix material 225 cooperate to reduce the oxidation rate of metal nanoparticles 240. For example, metal nanoparticles 240 may form chemical bonds with matrix material 225 to eliminate or reduce the number of bonds available for binding with oxygen. This in turn eliminates the need for keeping the cermet under vacuum and hence offers an improvement to lifetime, reliability, complexity, and cost CSP systems.

FIG. 3 shows an antioxidation, spectrally selective absorber 300 that is a particular embodiment of spectrally selective absorber 200 of FIG. 2. In antioxidation absorber 300, matrix 220 includes a matrix material 325 and metal nanochains 240 composed of one or more metal nanoparticles 230. Matrix material 325 and nanoparticles 240 cooperate to form chemical bonds 350 occupying sites otherwise available for reaction with oxygen. In certain embodiments, matrix material 325 contains Si, a Si—O network, Ge, a Ge—O network, a Si—C—O network, a Ge—C—O network, and/or a Si—Ge—C—O network; and metal nanoparticle 240 is composed of a metal that has a high absorption coefficient in the solar spectrum and forms chemical bonds with Si, Ge, or C. Examples of precursors to form these matrix materials include HSQ (Hydrogen silsesquioxane), TEOS (tetraethyl orthosilicate), Germanium tetra-(tertiary butoxide), other precursors containing Si, Ge, O, or C diluted in organic or inorganic solvents, or a combination thereof. A particular example is illustrated in FIG. 12 and discussed in Example III.

FIG. 4 illustrates one method 400 of manufacturing a metal nanochain based spectrally selective absorber, for instance absorber 200 of FIG. 2 or antioxidation absorber 300 of FIG. 3. Metal nanochains (e.g., metal nanochains 230) are synthesized in a step 410 using solution-chemical processes. In an embodiment, step 410 involves mixing a compound containing positively charged metal ions, a reducing agent, and, optionally, an additional promoting agent for promoting formation of the desired form of nanostructures. Both the reducing agent and the promoting agent may be composed of a single component or two or more components. Optionally, addition solutions such as buffer solutions are added to achieve certain concentrations and/or keep other reagents in environments necessary for preservation of desired properties. The positively charged metal ions are reduced with the reducing agent to form neutral metal atoms. This redox reaction is performed in a solution that promotes aggregation of the neutral metal atoms into metal nanochains with the desired properties, e.g., metal nanoparticle size, hollow nanoparticles, solid nanoparticles, and length of nanochains. In certain embodiments, a promoting agent is added to the solution for this purpose. Examples of promoting agents include, but are not limited to, ethylene glycol, ethanol, organic solvents, hydroxide, and solutions containing hydroxide. Formation of the desired form of nanostructures also depends on the relative concentrations of the different substances in the solution, and, hence, the relative concentrations provide a tool for tuning, e.g., the nanoparticle diameter and the nanochain length. One can also introduce surfactants and co-surfactants to the metal nanochain and nanostructure fabrication. The presence of surfactants and co-surfactants is advantageous in forming microemulsions to facilitate spray coating. These surfactants include, but are not limited to, cetyl trimethylammonium bromide (CTAB), Dioctyl sodium sulfosuccinate (AOT), oleic acid, amines, Triton X-100, and butanol. The size of the droplets in microemulsions can be controlled by the water/surfactant ratio and water/oil ratio. Specific embodiments of step 410 are discussed below in Examples I, II, and III.

In a step 420, the metal nanochains produced in step 410, e.g., metal nanochains 230, are dispersed into a matrix solution, for example a solution containing matrix material 225 (FIG. 2) or 325 (FIG. 3), or a precursor to form matrix material 225 or 325. Proper dispersion is achieved using methods known to a person skilled in the art, for example sonication, vortexing, or magnetic stirring. In an embodiment, the matrix solution is a ceramic solution such that the solution after completion of method 400 forms a cermet, e.g., matrix 220 is a cermet. Generally, the matrix solution should be chosen such that the resulting matrix can withstand the temperatures encountered during manufacturing and operation of the system in which the spectrally selective absorber will be utilized.

In a step 430, the mixture formed in step 420 is coated onto a substrate, such as substrate 210, using, for instance, dip coating, drip coating, spray coating, roller coating, air knife coating, knife-over-roll coating, spin coating, or other solution-based coating methods. The coating process may be tailored to achieve a generally uniform concentration of nanochains throughout the matrix. In an embodiment, the mixture is applied to the substrate by spin coating. In particular embodiments, spin coating is performed in a sequence of increasing spin rates or at a gradually increasing spin rate to optimize the nanochain concentration uniformity. In certain other embodiments, a coating method such as dip coating or drip coating is utilized to conveniently coat a non-planar surface.

In a step 440, liquid is removed from the coating. This may be performed in a drying process, optionally at elevated temperature. In a step 450, the coating is annealed. In an embodiment, step 450 is performed in an inert atmosphere, e.g., under nitrogen and/or argon, or in a reducing atmosphere containing, for instance, hydrogen to prevent oxidation of the metal nanoparticles (e.g., metal nanoparticles 240) during annealing. In another embodiment, the annealing process is optimized to provide improved adhesion between the substrate and the coating, e.g., between substrate 210 and matrix 220. Optionally, a series of different annealing temperatures may be utilized in step 450. In one embodiment, improved adhesion and/or thermal stability of the coating to the substrate is achieved by a two-step annealing process consisting of a lower temperature step and a higher temperature step. To enhance the long-term antioxidation properties, for the second step of annealing one can anneal in inert or slightly reducing ambient at >750° C., or in oxidizing ambient at >600° C. The purpose of the annealing step is to form Si-rich silicides such as NiSi₂, CrSi₂ and/or CoSi₂ that are more robust (or more resistant) to long-term oxidation. In certain embodiments, steps 440 and 450 are combined in a single step. For example, drying of the liquid may occur in the early stages of an annealing process.

### Example I

### Ni Nanochain-Al₂O₃ Spectrally Selective Solar Thermal Absorber

This example constitutes a particular embodiment of absorber 200 of FIG. 2, optimized for use as a spectrally selective solar thermal absorber, wherein metal nanoparticles 240 are Ni nanoparticles and, hence, nanochains 230 are Ni nanochains. Matrix 220 is a cermet composed of Al₂O₃ with embedded Ni nanochains. The diameter of the Ni nanoparticles is about 100 nm, which is sufficiently small to not be resolved by short-wavelength infrared and mid-infrared photons from thermal radiation. The fabrication method described in this example is an embodiment of method 400 of FIG. 4. The matrix material Al₂O₃ has been chosen for its ability to withstand high temperatures. Further, Al₂O₃ is an inexpensive material commonly used in many different systems and application. Other suitable matrix materials include aluminum nitride, silicon oxide, and silicon oxynitride.

### Theory

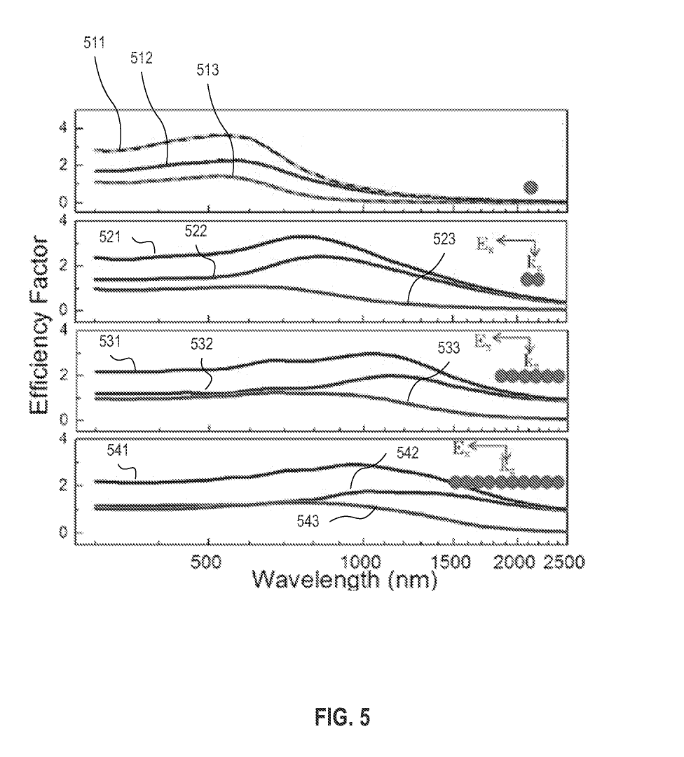

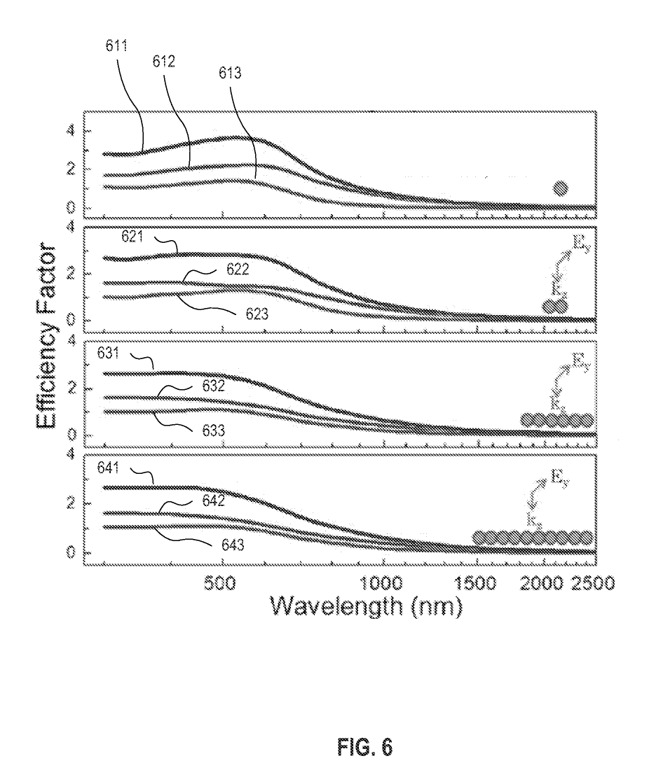

In order to understand the plasmonic effect of Ni nanochains, the absorption, scattering, and extinction efficiency factors of individual Ni nanochains were calculated by a 3D finite-element method (FEM) and shown in FIGS. 5 and 6. The nanochains are composed of a series of connected Ni nanoparticles with a diameter of 80 nm, and the chains are 1-, 2-, 6-, and 10-nanoparticle long. The efficiency factors presented In FIGS. 5 and 6 are absorption/scattering/extinction cross-sections normalized by the geometric area of the nanostructures and thereby unitless. The dielectric functions of Ni and Al₂O₃ were obtained from E. D. Palik, Handbook of Optical Constants of Solids (Academic, Boston, 1985). To improve the computation efficiency based on the symmetry of the structure, only one quarter of the domain was calculated using adequate boundary conditions. To check the validity of FEM method, the absorption/scattering/extinction efficiency factors of one Ni nanoparticle were calculated and found to be highly consistent with analytical solutions based on Mie scattering theory generated using MiePlot 4.0 Software (Philip Laven, Switzerland). Incident plane waves propagating in the z direction with linear x-polarization (along the nanochain) were analyzed and the corresponding FEM results are shown in FIG. 5. Equivalently, y-polarization (perpendicular to the nanochain) was analyzed and FEM results shown in FIG. 5. The traces in FIG. 5 are labeled “5ij”, where “i” is an indicator number for the number of nanoparticles in the nanochain and “j” is an indicator for the type of optical property. Specifically, i=1, 2, 3, and 4, respectively, for 1, 2, 6, and 10 nanoparticles. j=1, 2, and 3, respectively, indicate the efficiently factors for extinction, absorption, and scattering. The traces in FIG. 6 are labeled “6ij” following the same convention as for FIG. 5. As summarized in FIGS. 5 and 6, the optical response of the individual nanochain is dependent on the polarization direction. For incident light polarized in the x-direction along the nanochain, the optical response spectrum is extended from a wavelength of 1000 nm to 2500 nm with the increase of nanoparticle numbers, covering more than 99% of optical energy in the solar spectrum. Such spectrum broadening saturates when the number of nanoparticles in a nanochain is large enough, as evidenced by the similarities of optical response from 6- and 10-nanosphere chains in FIG. 5.

To further elucidate the mechanism of extended absorption spectrum with the number of particles in a nanochain, the optical field distribution at a wavelength of 2500 nm under x-polarization was investigated. The optical field was found strongly enhanced at the narrow gaps between nanoparticles due to near-field plasmonic effects, an advantage over nanorod structures in terms of surface plasmon polariton enhancement. The 6-nanoparticle chain shows a stronger field enhancement than the 2-nanoparticle one at a wavelength of 2500 nm, confirming that the increase in absorption at longer wavelengths, i.e., above 2000 nm, is indeed related to the surface plasmon polariton effect. It is likely that plasmonic coupling among a larger number of nanoparticles leads to a stronger field enhancement at the gaps between nanoparticles. When the number of nanoparticles becomes large enough, the plasmonic coupling among them reaches a steady state, which qualitatively explains the saturation in spectral broadening.

On the other hand, for incident light polarized in the y-direction perpendicular to the nanochain, FIG. 6 shows that the absorption/scattering/extinction efficiency factors are not sensitive to the nanochain length, as one would expect. In contrast to x-polarization, the optical field distribution between nanoparticles is almost the same for 2-nanosphere and 6-nanosphere chains. In the real cermet structures with randomly oriented nanochains, optionally forming three-dimensional networks, the optical response is polarization-independent. It is an average of the two cases in FIGS. 5 and 6. The multi-scattering among nanochains may also enhance the overall absorption.

### Cermet Fabrication

Ni nanochain-Al₂O₃ cermet coatings were fabricated by a solution-chemical process. First, Ni nanochains with a Ni nanoparticle diameter of about 80 nm and a Ni nanochain length of two to three μm are synthesized by reducing Ni²⁺ with N₂H₄. Next, the Ni nanochains were dispersed in an Al₂O₃ solution for spin coating on 25 μm thick, 20×20 mm² stainless steel substrates. Finally, the samples were annealed at 400° C. for one hour in N₂ to form a 1 μm thick cermet coating. The surface of the Ni nanochain-Al₂O₃ cermet layer visually looked black, as expected for solar thermal coatings. Scanning electron microscopy showed that the Al₂O₃ nicely covered the Ni nanochains. The manufacturing method is illustrated in FIG. 7.

FIG. 7 illustrates a method 700 for fabrication of the Ni nanochain-Al₂O₃ cermet coatings of the present example. This is a particular embodiment of method 400 of FIG. 4 and is used to produce a particular embodiment of absorber 200 of FIG. 2. As discussed in detail below, Ni nanochains are produced by steps 710 through 714, and the Al₂O₃ material is produced by steps 720 through 726. These two components are combined and the absorber manufacturing completed in steps 730 through 760.

In a step 710, 45 nM nickel chloride is dissolved in ethylene glycol. In a step 712, 0.9 M hydrazine and 1.0 M NaOH solution (72 μl/ml) are added in sequence. In a step 714, the solution formed in step 712 is stirred in a capped bottle at a temperature of 60° C. for about one hour, after which Ni nanochains are formed. The reduction reaction can be expressed as:

2Ni²⁺+N₂H₄+OH⁻=2Ni+N₂+4H₂. (1)

The size of the Ni nanoparticles in the nanochains is controlled by the ratio of NiCl₂ to N₂H₄.

In a step 720, 2.04 g (0.01 mol) aluminum isopropoxide is dissolved in 200 ml deionized water at 80° C. In a step 722, the solution is allowed to hydrolyze at 80° C. for about one hour. In a step 724, nitric acid is added to the solution to reach a pH value of 3. In a step 726, the temperature is increased to 90° C. to speed up the polymerization process and the solution is stirred for about two hours in an open beaker.

In a step 730, 50 mg Ni nanochains formed in step 714 and 2 ml Al₂O₃ suspension formed in step 726 are ultrasonically mixed together to form a black slurry. In a step 740, the slurry is spin-coated on a 25 μm thick, 20×20 mm² sized stainless steel substrate. A syringe with approximately 0.5 ml of coating suspension is used to eject the liquid onto the center of the substrate, first for about 10-20 seconds at a rotational speed of 500 rpm, next for about 30 seconds at a rotational speed of 3000 rpm. In a step 750, the film is dried at 100° C. for 15 minutes. The series of steps 730, 740, and 750 is performed four times before proceeding. In a step 760, the film is annealed at 400° C. for 1 hour in N₂ atmosphere to produce an about one μm thick Ni nanochain-Al₂O₃ cermet coating.

### Results and Discussion

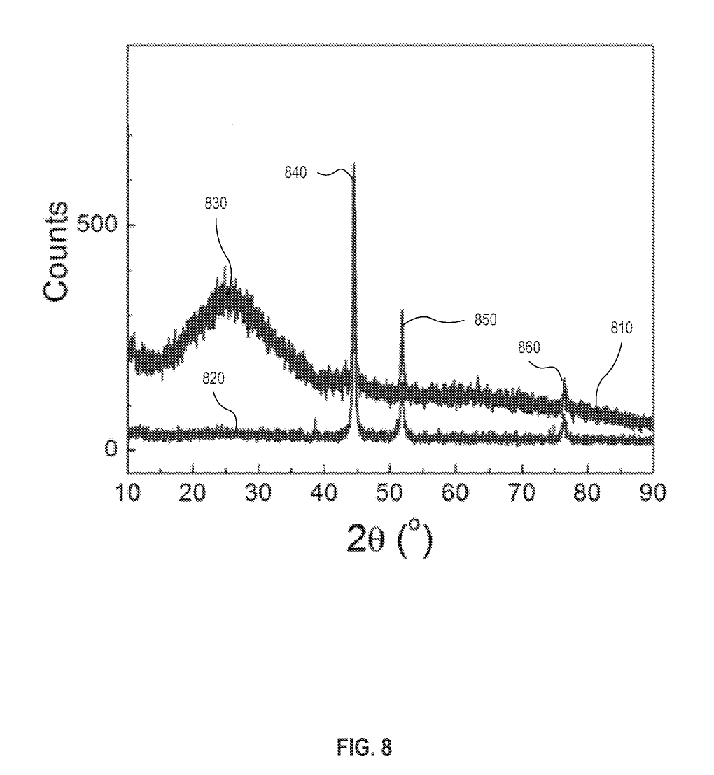

Proper nanochain synthesis was confirmed by scanning electron microscopy of the synthesized Ni nanochains prior to dispersion in the Al₂O₃ suspension. It was observed that Ni nanochains did not separate into individual nanoparticles even under strong ultrasonic vibration. Scanning electron microscopy of the coated and annealed Ni nanochain-Al₂O₃ cermet further showed that the Al₂O₃ nicely covered the Ni nanochains. The surface of the Ni nanochain-Al₂O₃ cermet layer visually looked black, as expected for solar thermal coatings. FIG. 8 shows x-ray diffraction data of the Ni nanochain-Al₂O₃ layer (trace labeled 810) in comparison with as-synthesized Ni nanochains alone (trace labeled 820). The bump at 20° C. (830) corresponds to an amorphous Al₂O₃ matrix, while the three distinct peaks 840, 850, and 860 correspond to Ni (111), Ni (200), and Ni (220), respectively. Compared to as-synthesized Ni nanochains, it is clear that there is no modification in crystal structure or formation of Ni oxide during the annealing process.

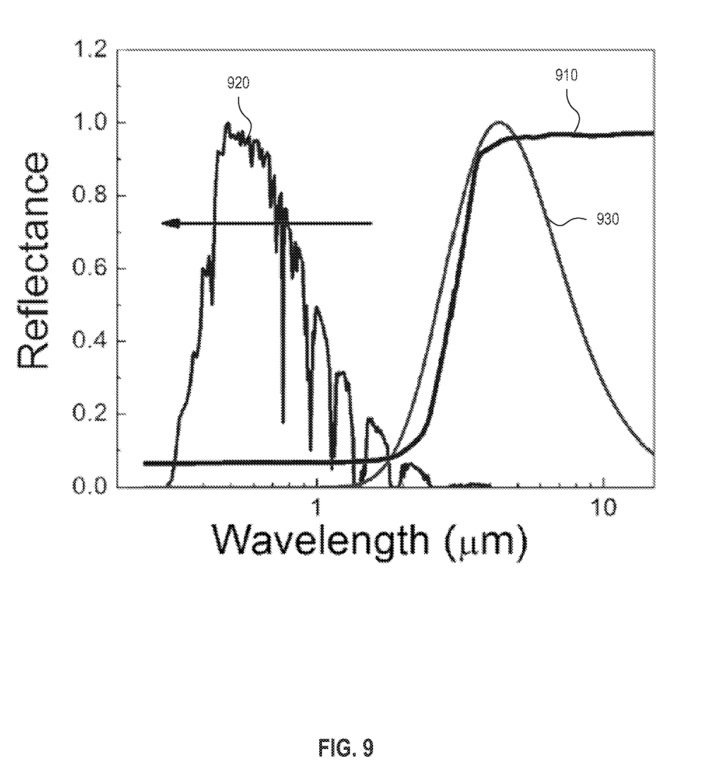

The reflection of the Ni nanochain-Al₂O₃ cermet coating in the wavelength range of 0.2-2.5 μm was measured using a UV-VIS-NIR spectrometer with an integrating sphere to collected both specular and diffuse reflection, and the reflection in the infrared range of 2.5-20 μm was obtained using a Fourier transform infrared spectroscopy equipment. FIG. 9 shows the reflectance spectrum (trace 910) of the Ni nanochain-Al₂O₃ cermet coating in the wavelength range of 0.3-15 μm. The Air Mass (AM) 1.5 solar spectrum (trace 920) and black-body radiation spectrum at 400° C. (trace 930) are also shown as a reference. According to Kirchhoff's law, at each wavelength λ the absorptance α(λ) is equal to the emittance ∈(λ) under thermal equilibrium. Since the transmittance through the stainless steel substrate is 0, the absorptance/emittance at each wavelength is equal to one minus the reflectance at that wavelength:

α(λ)=∈(λ)=1−R(λ)−T(λ)=1−R(λ). (2)

Here R(λ) and T(λ) are reflectance and transmittance at wavelength λ, respectively. Consequently, a low reflectance is desirable in the solar spectrum regime of λ=0.3-2.5 μm for high solar absorptance, while a high reflectance is desirable in the mid-infrared regime at λ>3 μm for low thermal emittance. The reflectance of the Ni nanochain-Al₂O₃ cermet coating is 0.06-0.09 in the wavelength range of λ=0.3-2.1 μm, leading to high solar absorptance. The reflectance starts to increase significantly at λ>2.1 μm, indicating a drastic decrease in absorption. This transition point corresponds well to the roll-off in the calculated absorption/scattering/extinction spectra of Ni nanochains at λ>2 μm, as shown in FIG. 5. Therefore, the optical performance of this Ni nanochain-Al₂O₃ cermet structure is consistent with theoretical predictions. The reflectance is greater than 0.9 at λ>3.5 μm, leading to low thermal emittance in the MIR regime.

The overall solar absorptance, αₛₒₗ, and overall thermal emittance, ∈ₜₕₑᵣₘ, are derived from the reflectance spectrum using the following equations:

$$\begin{matrix}{α}_{sol} = \frac{{\int }_{0.3 µm}^{2.5 µm} {I}_{sol} ( λ ) α ( λ ) d λ}{{\int }_{0.3 µm}^{2.5 µm} {I}_{sol} ( λ ) d λ} = \frac{{\int }_{0.3 µm}^{2.5 µm} {I}_{sol} ( λ ) [ 1 - R ( λ ) ] d λ}{{\int }_{0.3 µm}^{2.5 µm} {I}_{sol} ( λ ) d λ} & ( 3 A ) \\ {ɛ}_{therm} = \frac{{\int }_{2 µm}^{20 µm} {I}_{P} ( λ ) ɛ ( λ ) d λ}{{\int }_{2 µm}^{20 µm} {I}_{P} ( λ ) d λ} = \frac{{\int }_{2 µm}^{20 µm} {I}_{P} ( λ ) [ 1 - R ( λ ) ] d λ}{{\int }_{2 µm}^{20 µm} {I}_{P} ( λ ) d λ} & ( 3 B )\end{matrix}$$

Here Iₛₒₗ(λ) is the radiation intensity at wavelength λ in AM 1.5 solar spectrum and I_{P}(λ) is the radiation intensity at wavelength λ in 400° C. black-body radiation spectrum. The overall solar absorptance is determined to be 93%, and the overall thermal emittance is 9% for the current structure. A small amount of solar energy may be scattered by Ni nanochains and absorbed by the stainless steel substrate, which also contributes to the overall solar to thermal energy conversion. This optical performance is comparable to conventional multilayer cermets manufactured using vacuum deposition methods. However, the present performance is achieved using simpler and cheaper manufacturing methods. The performance can be further optimized by fine tuning the nanoparticle sizes to better match the solar spectrum and the 400° C. black-body radiation spectrum.

In conclusion, plasmonic Ni nanochain-Al₂O₃ cermet structures were fabricated by a cost-effective solution-chemical approach for solar thermal applications. Unlike conventional multilayer graded-index cermet coatings, surface plasmon polariton enhanced solar absorption in these nanostructures was tailored by the lengths of Ni nanochains instead of cermet layer thicknesses, eliminating the requirement of costly vacuum deposition for stringent thickness control. High solar absorptance greater than 90% and low thermal emittance losses below 10% have been demonstrated in these Ni nanochain-Al₂O₃ cermet coatings, comparable to the performance of vacuum deposited selective cermet absorbers.

### Example II

### Synthesis of Ni Nanochains Consisting of Hollow Ni Nanoparticles

This example illustrates one embodiment of step 410 of FIG. 4 to form hollow Ni nanoparticles and chains thereof, which constitute embodiments of, respectively, nanoparticles 240 and nanochains 230 of FIGS. 2 and 3.

Hollow Ni nanoparticles and nanochains are fabricated using a hydrothermal method for the formation of nanometer-sized Ni spheres via the redox reaction of nickel dodecylsulfate (Ni(DS)₂) with NaH₂PO₂ in a Ni(DS)₂ micelle system. FIG. 10 illustrates a general method 1000 for forming hollow Ni nanoparticles. Ni(DS)₂, labeled 1010, is dissolved in water to form spherical micelle templates 1020, and Ni²⁺ ions react with H₂PO²⁻ to form Ni atoms 1030 in the presence of OH⁻. Next, Ni atoms aggregate and develop gradually, as illustrated by label 1040, into Ni hollow nanoparticles 1050. The presence of OH⁻ plays a critical role in forming shell structure instead of solid nanoparticles. The size, shell thickness and size distribution of hollow Ni nanoparticles may be tailored by the concentration of Ni(DS)₂, temperature and time of the synthesis process.

FIG. 11 shows a more detailed method 1100 for forming hollow Ni nanoparticles. Method 1100 is a particular embodiment of method 1000. In a step 1110, Ni(DS)₂ is formed from raw materials of nickel chloride and sodium dodecylsulfate. In a step 1120, a certain amount of Ni(DS)₂ is added to distilled water and stirred, in a step 1130, for several minutes at 40° C. to ensure the complete dissolution of Ni(DS)₂ micelle system. The concentration of Ni (DS)₂ is an important parameter in forming the Ni(DS)₂ micelle template and it should be greater than 1×10⁻³ M. In a step 1140, NaH₂PO₂.H₂O and NaOH is added to the solution formed in step 1130. In this method, the presence of OH⁻ plays a critical role in forming shell structure instead of solid spheres and provides a tuning parameter for achieving a desired shell thickness. In a step 1150, the resulting solution is transferred to the autoclave bottle lined with polytetrafluoroethylene (Teflon). The autoclave bottle is sealed and maintain at a typical synthesis temperature of 100° C. for several hours. Finally, in a step 1160, the black Ni deposits are collected, washed, separated and dried to obtain the pure hollow Ni nanoparticles. The size, shell thickness and size distribution of hollow Ni nanoparticles can be tailored by the concentration of Ni(DS)₂, temperature and time of the synthesis process. Synthesis of hollow Ni nanochains can be achieved by applying adequate solvents in step 1140, e.g. ethylene glycol or ethanol solutions.

Hollow nanoparticles have at least two advantages compared to solid nanoparticles: (a) less material is required to form hollow nanoparticles, and (b) the shell thickness constitutes an additional parameter that can be tuned to achieve the desired optical response properties.

### Example III

### Antioxidation, Metal-Nanostructure Based Spectrally Selective Solar Thermal Absorbers

In this example, a method is disclosed for fabricating spectrally selective solar thermal absorbers in accord with system 300 of FIG. 3, method 400 of FIG. 4, and, optionally, methods 700 (FIG. 7), 1000 (FIG. 10), and/or 1100 (FIG. 11). In this particular embodiment, the nanochains (e.g., nanochains 240) are protected against oxidation. This has important implications for CSP systems where the presently disclosed antioxidation spectrally selective solar thermal absorber may be incorporated at ambient atmosphere, as opposed to being kept under vacuum. The nanoparticles may consist of hollow and/or solid nanoparticles. In certain embodiments, the nanochains are composed of a plurality of nanoparticles in the range of 2-10,000 nanoparticles.

### Absorber Fabrication

FIG. 12 shows a method 1200 for fabricating an antioxidation spectrally selective solar thermal absorber, e.g., absorber 300 of FIG. 3, based on Ni nanoparticles or Ni nanochains. The Ni nanostructures (e.g., nanochains 230) are synthesized in a step 1210 using, for instance, the methods discussed in connection with step 410 of FIG. 4, or illustrated in FIGS. 7, 10, and 11. In a step 1220, the Ni nanostructures are mixed with a matrix precursor. The matrix precursor is HSQ diluted with MIBK (methyl isobutyl ketone) at a ratio in the range 1:3 to 1:10. The matrix material HSQ (e.g., matrix material 325) contains Si and a Si—O network. Uniform dispersion of the Ni nanostructures in the matrix precursor is achieved by sonication for about 10 minutes to 2 hours. Alternatively, the Ni nanostructures can be mixed with a matrix precursor including TEOS and/or germanium tetra-(tertiary butoxide) diluted in an organic or inorganic solvent.

In a step 1230, the mixture is coated onto a substrate, e.g., substrate 210, using a multi-step spin coating process. In order to improve the uniformity of the coating, the spin coating process consists of a first spin rate at less than 600 rpm followed by a second spin rate greater than 600 rpm and less than 3000 rpm. In a step 1240, the coating is dried, e.g., by exposure to elevated temperature using standard methods known to a person skilled in the art such as placing the sample on a hot plate. In a step 1250, the sample is subjected to a two-step annealing process in a nitrogen atmosphere consisting of annealing first at a temperature less than 500° C. and next at a temperature greater than 600° C. The two-step annealing process results in improved adhesion of the coating to the substrate compared a standard annealing process performed at a single, constant temperature. During the annealing process, the Ni nanostructures form chemical bonds with Si, a Si—O network, and/or a Si—O—Si cage in the HSQ matrix. Optionally, annealing is performed under Argon atmosphere, or another inert or slightly reducing atmosphere. To enhance the long-term antioxidation properties, for the second step of annealing one can anneal in inert or slightly reducing ambient at >750° C., or in oxidizing ambient at >600° C. The purpose of the annealing step is to form Si-rich silicides such as NiSi₂, CrSi₂ and/or CoSi₂ that are more robust (or more resistant) to long-term oxidation. In an alternative embodiment, annealing is performed at a single temperature of 300-900° C. for about 2 minutes to one hour.

### Results and Discussion

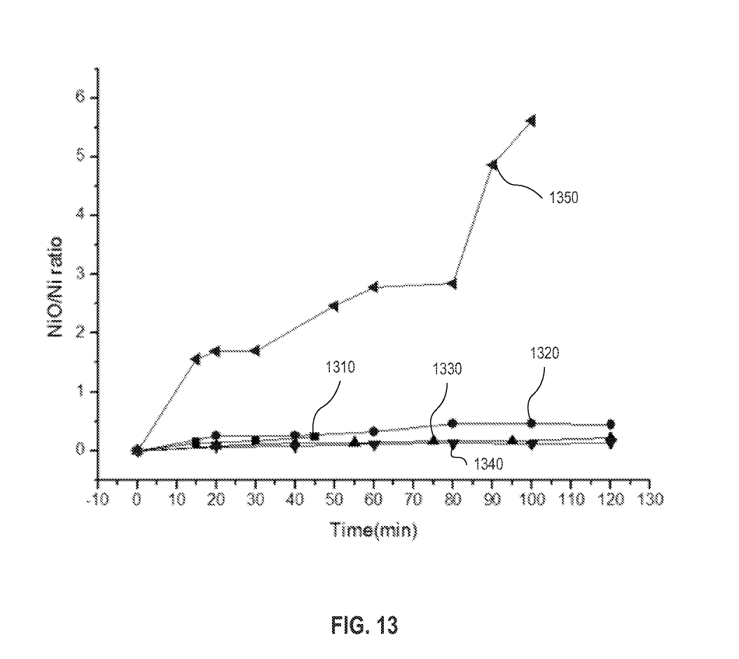

The antioxidation properties of the Ni nanostructure-HSQ matrix in air were tested at temperatures up to 600° C. Ni nanochain-HSQ absorber samples were heated in air and their oxidation behavior characterized by x-ray diffraction. For reference, samples of Ni nanostructure-Al₂O₃ fabricated according to method 700 of FIG. 7 underwent the same test. FIG. 13 shows the ratio of the NiO peak to the Ni peak in the x-ray diffraction spectrum as a function of time for Ni nanostructure-HSQ at 450° C. (trace 1340), 550° C. (trace 1330), and 600° C. (trace 1320) together with reference data for Ni nanostructure-Al₂O₃ at 450° C. (trace 1350). The results show that the Ni nanostructures in the nanostructure-Al₂O₃ system readily oxidize at 450° C. while the Ni nanochain-HSQ system shows little oxidation at the highest tested temperature of 600° C.

The concepts of this example can be extended to other systems based on metal nanostructures that form stable chemical bonds with a matrix without departing from the scope of the present disclosure. For example, antioxidation behavior at temperatures up to 550° C. has been achieved for a Ni nanochain-TEOS based absorber (see FIG. 13, trace 1310), which offers cost benefits over the Ni nanostructure-HSQ system due to lower material cost of TEOS than HSQ. Examples of alternatives to Ni include Fe, Co, Cr, W, and Ta. Any metal material that has a high absorption coefficient in the solar spectrum and forms chemical bonds with Si, Ge or C can be used. Furthermore, the antioxidation systems and methods of this example can be extended to other types of applications and systems without departing from the scope hereof. The systems and methods disclosed in the present example have utility in a wide array of nanostructure applications, wherein the nanostructures are subject to degradation by oxidation, for example metal nanostructures located in a hot and/or humid atmosphere or in a liquid environment. Exemplary applications include, but are not limited to, spectrally selective solar thermal absorbers in CSP systems and spectrally selective emitters in thermovoltaic systems. The latter application is discussed in Example IV below.

### Example IV

### Metal-Nanostructure Based Spectrally Selective Emitter

In a thermophotovoltaic system, a photovoltaic cell converts thermal radiation emitted by a heat source to electricity. Efficient conversion of thermal radiation to electricity relies on a good match between the thermal radiation spectrum and the bandgap of the semiconductor material in the photovoltaic cell. Thermophotovoltaic systems therefore utilize semiconductor materials with a relatively low bandgap. However, the absorption spectra associated with semiconductor bandgaps are generally narrower than the thermal radiation spectrum and are centered at values corresponding to radiation from heat sources at temperatures of at least 1000° C. Therefore, some thermophotovoltaic systems include spectrally selective emitters to modify the spectrum of the thermal radiation by reflecting back to the heat source at least portions of the thermal radiation not matched to the bandgap. The back reflected radiation is recycled by reabsorption in and remission from the heat source, and an overall increase in conversion efficiency results therefrom. Currently, spectrally selective emitters containing rare earth elements such as Erbium and Ytterbium are applied in these spectrally selective emitters. This example discloses a metal-nanostructure based spectrally selective emitter for thermophotovoltaic systems, which, in comparison with the rare earth based emitters, is both cheaper and composed of more readily available materials.

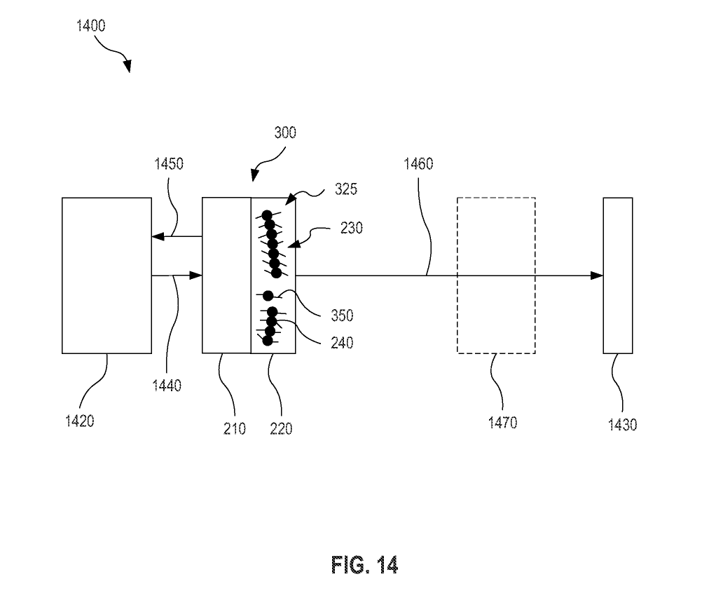

FIG. 14 illustrates a thermophotovoltaic system 1400 utilizing metal nanostructure-based, antioxidation, spectrally selective absorber 300 of FIG. 3 as a spectrally selective emitter. System 1400 includes a heat source 1420, antioxidation, spectrally selective absorber 300, and a photovoltaic cell 1430. Thermal radiation 1440 emitted by heat source 1420 in the direction towards photovoltaic cell 1430 must pass through antioxidation, spectrally selective absorber 300, either directly or by absorption and/or scattering in selective absorber 300. Light reflected and transmitted by selective absorber 300 is indicated in FIG. 14 by arrows 1450 and 1460, respectively. Optionally, system 1400 includes one or more optical elements 1470 such as concentrators, lenses, mirrors, and/or filters. The optical properties of nanostructures 230 and nanoparticles 240 are tuned to reflect light from at least portions of the thermal radiation spectrum that is of longer wavelength than the bandgap of photovoltaic cell 1430.

In certain embodiments, spectrally selective absorber 300 is manufactured using one or more of methods 400, 1000, 1100, and 1200 of FIGS. 4, 10, 11, and 12, respectively. Spectrally selective absorber 300 is protected from oxidation-induced degradation by manufacturing spectrally selective absorber 300 with oxidation-preventing bonds 350 between nanostructures 230 and matrix material 325 as discussed in connection with FIG. 3 and specifically illustrated in Example III and by method 1200 of FIG. 12. Antioxidation, spectrally selective emitters according to this embodiment are well suited for implementation in a thermophotovoltaic system where the high temperatures otherwise could lead to undesirable oxidation of the metal nanostructures.

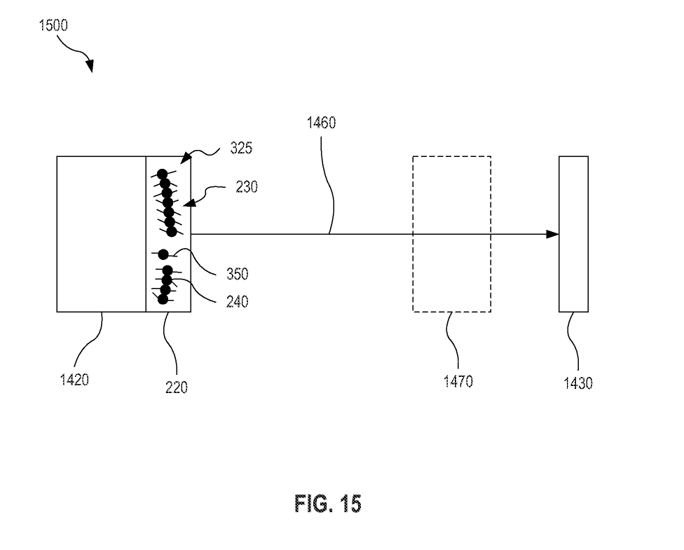

While FIG. 14 shows selective absorber 300 located at a distance from heat source 1420, it is contemplated that selective absorber 300 may be in direct contact with heat source 1420. Similarly, in an embodiment illustrated in FIG. 15 as thermophotovoltaic system 1500, substrate 210 is omitted and matrix 220 is applied directly to the surface of heat source 1420.

A modification to thermophotovoltaic systems 1400 (FIG. 14) and 1500 (FIG. 15) is contemplated, in which the spectrally selective emitter is spectrally selective absorber 200 of FIG. 2 without the antioxidation properties of antioxidation absorber 300, and wherein spectrally selective absorber 200 is kept under vacuum to prevent oxidation-induced degradation.

### Example V

### Tuning of Optical Response Properties of Metal Nanostructures

The optical response properties of metal nanostructures such as those disclosed herein may be tuned using a number of methods described in the following. These methods are applicable to methods 400, 700, 1000, 1100, and 1200 of FIGS. 4,7,10,11, and 12, respectively. In an embodiment, the metal nanoparticle size is controlled by, e.g. changing the ratio of metal ions to the reducing agent. Increasing the size shifts the spectral response to longer wavelengths. For instance, in Example III: Antioxidation, metal-nanostructure based spectrally selective solar thermal absorbers, increasing the diameter of the solid sphere from 100 to 300 nm can extend the spectral response range from 0.6 to 1.5 microns. In another embodiment, the nanochain length is controlled by varying the solvents and changing the surface energy of the nanoparticles. Again, applied to Example III: Antioxidation, metal-nanostructure based spectrally selective solar thermal absorbers, increasing the length the nanochains from 2 spheres to >10 spheres at the same diameter of 80 nm extends the spectral response from 1 to 2.5 microns. In an embodiment of methods 1000 (FIG. 10) and 1100 (FIG. 11), the shell thickness of hollow-core nanoparticles or nanochains is controlled by, e.g., changing the concentration of OH⁻. For a nanosphere with a diameter of 240 nm, decreasing the shell thickness from 40 to 10 nm shifts the spectral response from 1 micron to 3 microns.

It is further possible to tune the optical response properties by material choice. For example, ferromagnetic metal nanostructures broadens the optical response due to additional damping causes by the ferromagnetic interactions. In metal nanostructures, e.g., metal nanoparticles or metal nanochains, composed of different metals, the relative concentration of the different metals provides tunability of the optical response. For instance, ferromagnetic and non-ferromagnetic metals may be combined to achieve a desired spectral broadening. In an embodiments, a metal nanoparticle is composed of different metals, the metal nanoparticles optionally being organized in larger nanostructures. In another embodiment, a nanostructure composed of different types of nanoparticles, each type being based on a single metal, and at least one type being based on a metal different from another type.

We have demonstrated solution-processed Ni nanochain-SiOₓ (x<2) and Ni nanochain-SiO₂ selective solar thermal absorbers that exhibit a strong anti-oxidation behavior up to 600° C. in air. The thermal stability is far superior to previously reported Ni nanoparticle-Al₂O₃ selective solar thermal absorbers, which readily oxidize at 450° C. The SiOₓ (x<2) and SiO₂ matrices are derived from hydrogen silsesquioxane (HSQ) and tetraethyl orthosilicate (TEOS) precursors, respectively, which comprise Si—O cage-like structures and Si—O networks. Fourier transform infrared spectroscopy (FTIR) shows that the dissociation of Si—O cage-like structures and Si—O networks at high temperatures may have enabled the formation of new bonds at the Ni/SiOₓ interface to passivate the surface of Ni nanoparticles and prevent oxidation. X-ray photoelectron spectroscopy (XPS) and Raman spectroscopy demonstrate that the excess Si in the SiOₓ (x<2) matrices reacts with Ni nanostructures to form silicides at the interfaces, which further improves the anti-oxidation properties. As a result, Ni—SiOₓ (x<2) systems demonstrate better anti-oxidation performance than Ni—SiO₂ systems. This anti-oxidation Ni nanochain-SiOₓ (x<2) coating also demonstrates excellent high-temperature optical performance, with a high solar absorptance of 90% and a low emittance of 20% measured at 300° C. These results open the door to atmospheric stable, high temperature, high-performance solar selective absorber coatings processed by low-cost solution-chemical methods for future generations of CSP systems.

To reduce the fabrication cost without sacrificing the performance of the cermet solar absorbers, recently we have developed solution-processed plasmonic Ni nanochain-Al₂O₃ selective solar thermal absorbers that have achieved a high solar absorptance >90% and a low thermal emittance <10% measured at room temperature. See Xiaoxin Wang, Haofeng Li, Xiaobai Yu, Xiaoling Shi, Jifeng Liu, High-performance solution-processed plasmonic Ni nanochain-Al₂O₃ selective solar thermal absorbers, Applied Physics Letter 101 (2012) 203109 (hereinafter referred to as Wang et al.). The spectral selectivity is inherent to the plasmonic response of the Ni nanochains, which can be tuned by their lengths or diameters via solution chemistry. In comparison with the conventional design, the performance of this new nanochain cermet is much less constrained by stringent film thickness requirement, thereby facilitating low-cost solution-based fabrication method. Also, the size of the Ni nanoparticles in the chains is in the order of 100 nm, ˜10× larger than those in conventional cermets. The increased size not only benefits the plasmonic enhancement of absorption in the solar spectrum regime, but also makes the nanochains more resistant to oxidation. However, in the Ni nanochain-Al₂O₃ system, Ni nanoparticles are still easily oxidized at ≧450° C. in air. It has been reported that introducing TiO₂ particles into the Ni-based cermets helped to form compounds with Ni and effectively reduced the oxidation rate, yet the corresponding impact on the optical properties is unknown. See for example M. A. Farrokhzad T. I. Khan, High temperature oxidation of nickel-based cermet coatings composed of Al₂O₃ and TiO₂ nanosized particles, Oxid. Met. 81 (2014) 267-285. We further describe solution-processed plasmonic Ni nanochain-SiOₓ (x≦2) selective solar thermal absorbers that exhibit a strong anti-oxidation behavior up to 600° C. in air with high optical performance, far superior to the 450° C. limitation for Ni nanoparticle-Al₂O₃ selective solar thermal absorbers.

### Preparative Procedures

Metal silicides are much more resistant to oxidation than metals while maintaining the metallic optical properties. See for example W. J. Strydom, J. C. Lombaard, and R. Pretorius R, “Thermal oxidation of the silicides CoSi₂, CrSi₂, NiSi₂, PtSi₂, TiSi₂ and ZrSi₂” Thin Solid Films 131 (1985) 215-231, and J. P. Gambino, E. G. Colgan, “Silicides and ohmic contacts”, Mater. Chem. Phys. 52 (1998) 99-146. We have introduced Si into the ceramic matrix material. It is believed that the excess Si in the matrix can form silicide-like chemical bonds with the metal nanostructures, thereby retarding the oxidation process.

Two types of cermet selective solar thermal absorbers have been fabricated, i.e., Ni nanochain-SiOₓ (x<2) absorbers and Ni nanochain-SiO₂ absorbers. The Ni nanochain-SiOₓ (x<2) absorber comprises a thin film with Ni nanochains embedded in a dielectric matrix of SiOₓ (x<2). The SiOₓ matrix is derived from hydrogen silsesquioxane (HSQ) diluted by methyl isobutyl ketone (MIBK). Based on the stoichiometry of the HSQ precursor (H₈Si₈O₁₂), x is approximately 1.5.

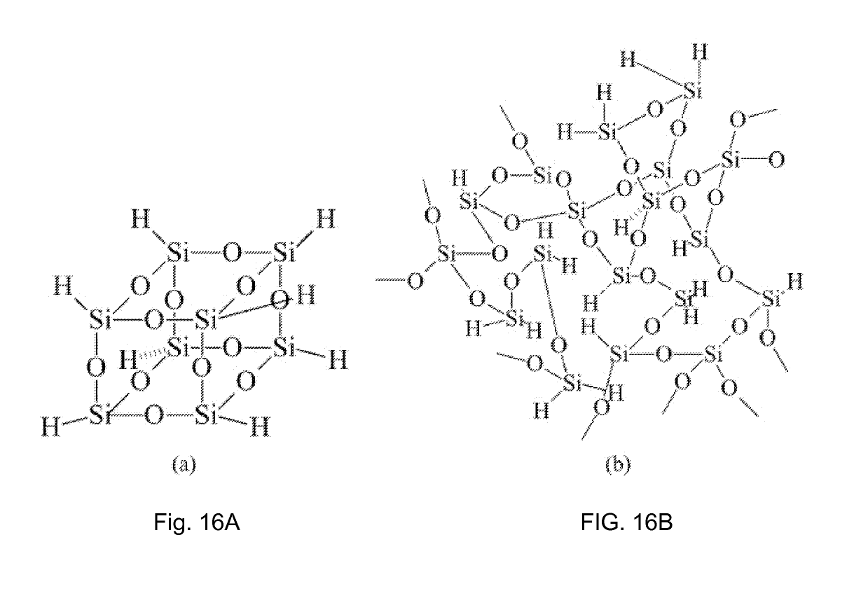

The molecular structure of HSQ is shown in FIG. 16A and FIG. 16B. FIG. 16A is a diagram of the chemical structure of HSQ in cage form. FIG. 16B is a diagram of the chemical structure of HSQ in network form. See Chang-Chung Yang, Wen-Chang Chen, “The structures and properties of hydrogen silsesquioxane (HSQ) films produced by thermal curing”, Journal of Materials Chemistry 12 (2002) 1138-1141. Under heat treatment at >700° C., the Si—H bonds, the Si—O cage-like structures, and the Si—O networks will start to dissociate (see for example, Colin M. Hessel, Eric J. Henderson, Jonathan G. C. Veinot, “Hydrogen silsesquioxane: A molecular precursor for nanocrystalline Si—SiO₂ composites and freestanding hydride-surface-terminated silicon nanoparticles”, Chemistry of Materials, 18 (2006) 6139-6146), potentially forming other chemical bonds with Ni nanoparticles. Since the SiOₓ (x<2) is Si-rich, the excess Si could also form silicide-like bonding with Ni nanostructures, as mentioned earlier. In order to observe the effect of excess Si in the matrix on oxidation prevention, we also fabricated a Ni nanochain-SiO₂ absorber as a comparison. In this case, the nanochains are embedded in a stoichiometric silica matrix derived from tetraethyl orthosilicate (TEOS) using sol-gel methods.

Nickel nanochains were fabricated by solution-chemical approach. The reaction is

2Ni²⁺+N₂H₄+OH⁻=2Ni+N₂+4H₂ (4)

The size of Ni nanoparticles is controlled by the Ni²⁺:N₂H₄ ratio, which is about 80 nm in this case. Besides, the Ni nanoparticles will automatically form Ni nanochains in ethylene glycol solution, which help to enhance the optical performance of the system due to the plasmonic effect in Ni nanochains. More details about the fabrication process can be found in Wang, et al.

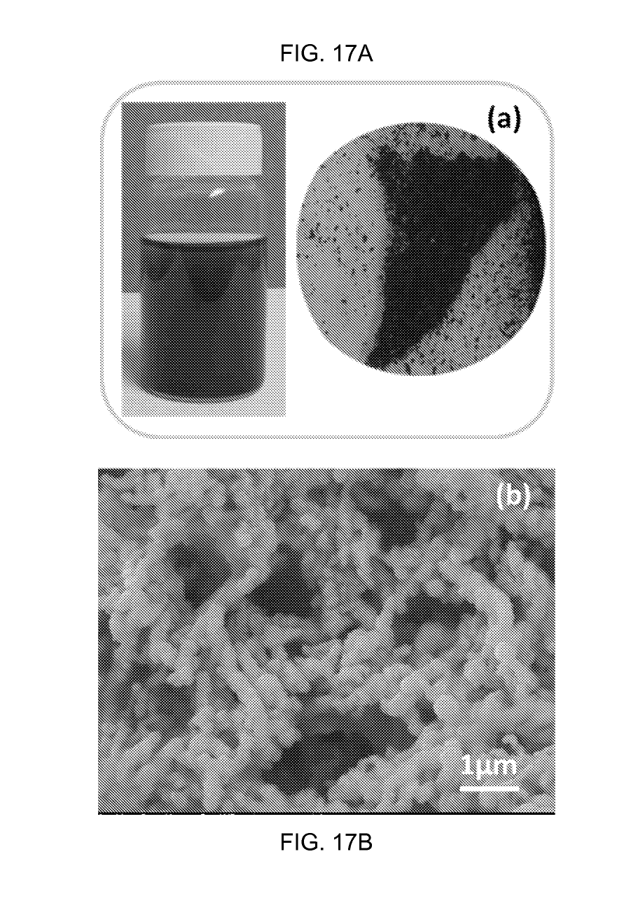

FIG. 17A is an image of a Ni nanochain suspension and powders.

For Ni nanochain-SiOₓ (x<2) cermet fabrication, HSQ was diluted with MIBK at a ratio from 1:3 to 1:10 with sonication. The Ni nanochains were mixed with the HSQ/MIBK solution and dispersed uniformly by sonication to form a sol before spin-coating. FIG. 17B is a scanning electron microscopy (SEM) image of Ni nanochain-SiOₓ (x<2) cermet.

For Ni nanochain-SiO₂ cermet fabrication, the SiO₂ sol was prepared by mixing TEOS, ethanol and deionized water with 37.2% wt HCl acid as catalyst, in a procedure similar to that described in A. Gungor, H. Demirtas, I. Atilgan, M. Yasar, Synthesis and characterization of SiO₂ films coated on stainless steel by sol-gel method, International Iron and Steel Symposium, 02-04 (2012). First, 18 ml TEOS and 12 ml ethanol were mixed with vigorously stirring for 30 min. Then, 10 drops of HCl was introduced to 20 ml deionized water. Next, the diluted HCl solution was slowly added into the TEOS-ethanol solution with vigorously stirring at 60° C. for 2 h. The Ni nanochains were mixed with the as-fabricated TEOS solution and dispersed uniformly by sonication to form a sol before spin-coating.

The two kinds of liquid mixtures were respectively spin-coated on Si or stainless steel substrates. The dimensions of the substrates were within 2×2 cm². The final step was to anneal the sample in a N₂, Ar or reducing-atmosphere (e.g. Ar with 5% H₂) at 700-800° C. for 15 to 30 min. Ni nanochain-Al₂O₃ cermet samples were also prepared using the methods described in Wang, et al. for comparison with Ni—SiOₓ and Ni—SiO₂ systems. The thickness of all the coatings are controlled to be ˜1 μm.

The anti-oxidation properties of the coated samples were tested in air from 450° C. to 675° C., and the samples were characterized by X-ray Diffraction (XRD, Cu Kα line, λ=0.15418 nm), X-ray photoelectron spectroscopy (XPS), Raman spectroscopy (excitation laser wavelength λ=514 nm) and Fourier transform infrared spectroscopy (FTIR) to investigate their crystal structures and chemical bonding. The optical properties at room temperature were characterized by a UV-VIS-IR spectrometer with an integrating sphere to measure the total reflectance (wavelength range from 300 to 2500 nm), while the high-temperature absorptance/emittance was obtained by directly measuring the emission spectra from the samples at 300° C. and normalizing the spectra to that of the black body reference.

### Anti-Oxidation Properties

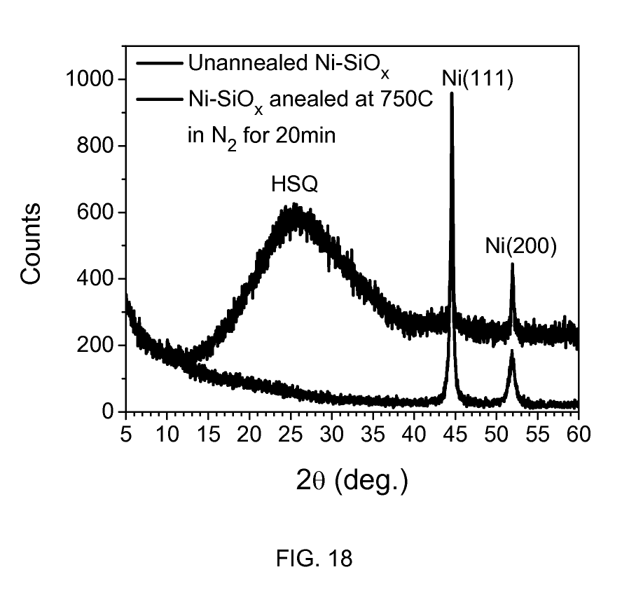

FIG. 18 shows the XRD data of Ni nanochain-SiOₓ (x<2) system coated on Si substrate before and after annealing in N₂ at 750° C. for 20 min. A bump around 25° can be clearly seen for the Ni nanochain-SiOₓ (x<2) sample before annealing compared to the data after annealing, which corresponds to the amorphous HSQ matrix. As will be shown later, the Si—O cages and network in HSQ dissociate after annealing, so the bump disappears. The two peaks at 44.5° and 51.8° correspond to Ni (111) and Ni (200), respectively. No Ni oxide peaks are found.

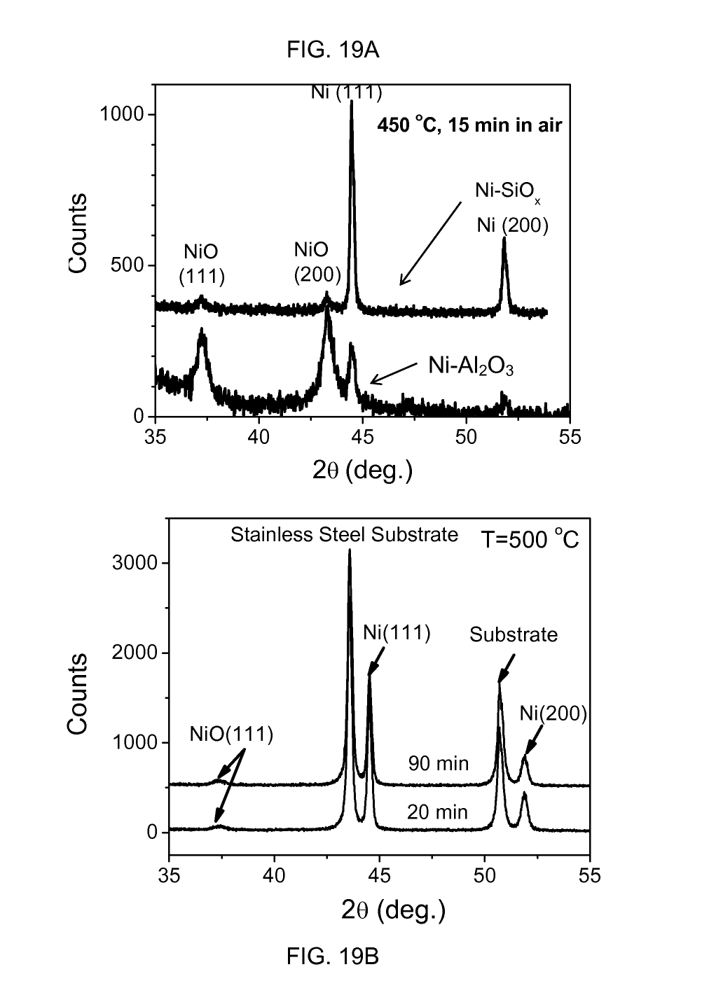

The Ni nanochain-SiOₓ (x<2) sample and a Ni nanochain-Al₂O₃ reference sample were then annealed at 450° C. in air for various durations and characterized by XRD each time to test their anti-oxidation properties. FIG. 19A is a plot of XRD data of Ni nanochain-SiOₓ (on Si) and Ni nanochain-Al₂O₃ coatings annealed in air at 450° C. for 15 min. Strong Ni oxide peaks (NiO (111), NiO (200), NiO (220)) show up in the Ni nanochain-Al₂O₃ spectrum (especially compared to the Ni peaks), while the Ni nanochain-SiOₓ (x<2) XRD pattern only show very little NiO signals. This result indicates that during the first 15 minutes of annealing in air, the Ni nanoparticles are much better protected from oxidation in the Ni nanochain-SiOₓ (x<2) system compared to the Ni nanochain-Al₂O₃ system.

FIG. 19B is a plot of XRD data of Ni nanochain-SiOₓ coating on stainless steel substrate annealed in air at 500° C. for 20 min and 90 min. The XRD pattern shows practically no change when the annealing time is increased from 20 min to 90 min, indicating that the oxidation process is retarded in the system at this temperature. The results in FIG. 18 and FIG. 1919B also indicate that the antioxidation behavior of the Ni nanochain-SiOₓ (x<2) coating is independent of the substrate.

For each XRD pattern, the intensity ratio of NiO (200)/Ni (111) was calculated to characterize the extent of oxidation because they are the strongest peaks in NiO and Ni, respectively. This helps to reduce the effect of measurement errors on the quantitative analysis of the oxidation process.

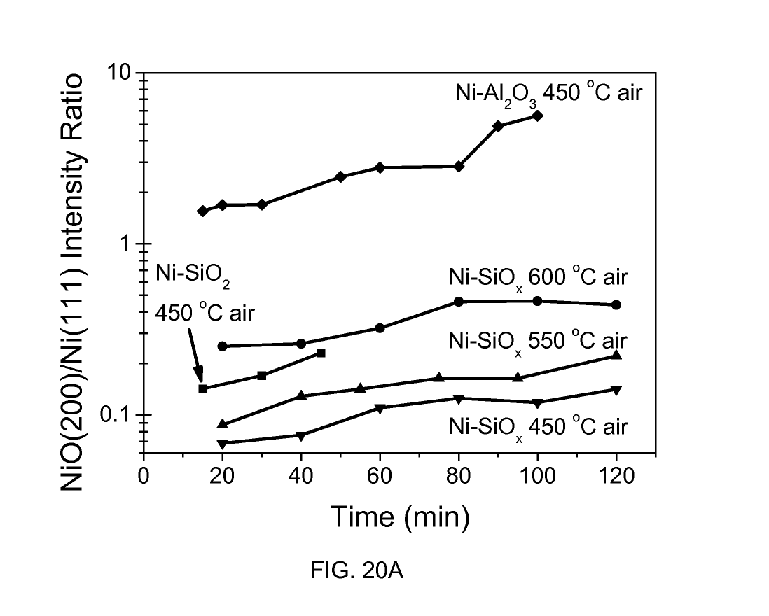

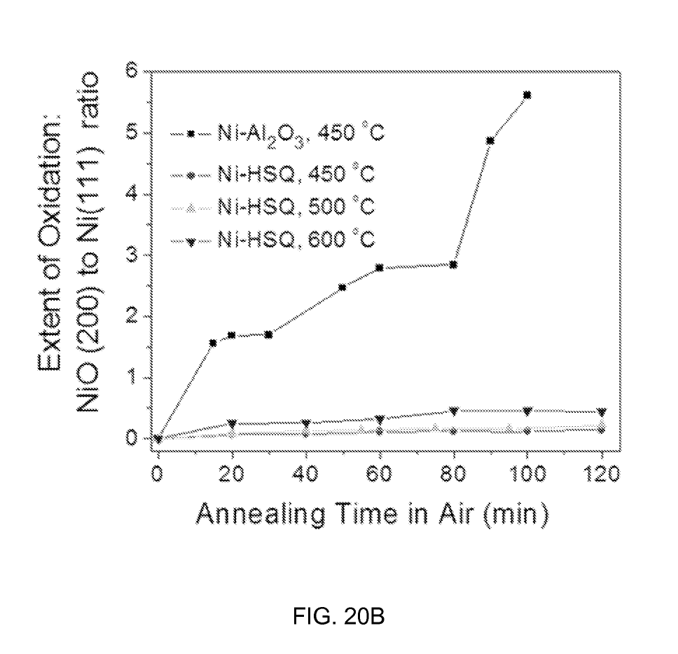

FIG. 20A is a graph of XRD peak intensity ratio for NiO(200)/Ni(111) as a function of annealing time at different temperatures (450-600° C.) for Ni—SiOₓ, Ni—SiO₂ and Ni—Al₂O₃ systems in air. The annealing was performed for period up to 2 h. The vertical axis is in log scale in order to show all the data clearly in the same plot. Clearly, the extent of oxidation in Ni—SiOₓ (x<2) and Ni—SiO₂ systems are 1-2 orders of magnitude lower than the Ni—Al₂O₃ system when annealed in air at 450° C. In fact, even after annealing at 600° C. in air, the NiO/Ni XRD peak ratio of the Ni—SiOₓ system is still an order of magnitude lower than the Ni—Al₂O₃ system annealed at 450° C. Compared to Ni—SiO₂ system, Ni—SiOₓ (x<2) system is more resistant to oxidation, as indicated by 3-4× lower NiO/Ni XRD peak ratio under the same annealing conditions. These results indicate that both the SiO₂ matrix itself and the excess Si in the matrix contribute to the anti-oxidation behavior. The mechanism will be discussed in more detail hereafter.

FIG. 20B is a graph of XRD peak intensity ratio of NiO(200) to Ni(111), as a function of annealing time for Ni—HSQ vs. Ni—Al₂O₃ cermet coatings at different temperatures. Even after 600° C. annealing, the Ni—SiOₓ shows orders of magnitude less oxidation than Ni—Al₂O₃ annealed at 450° C. in air. The vertical axis is linear.

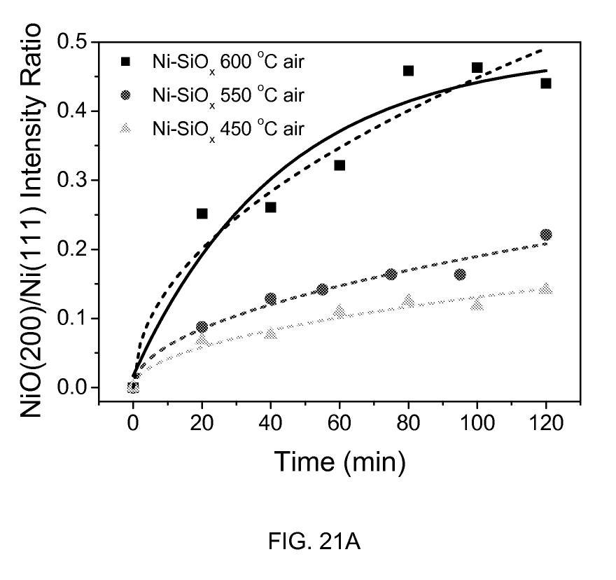

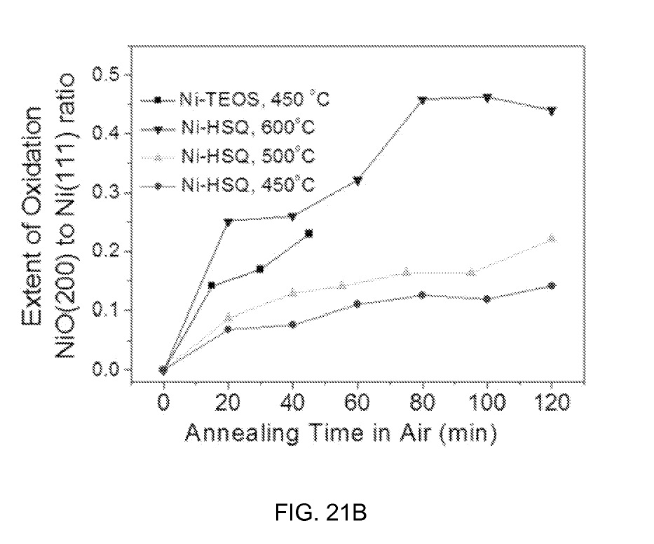

To analyze the oxide growth mechanism in Ni—SiOₓ system at 450-600° C., we applied the Deal-Grove model (see B. E. Deal, A. S. Grove, General Relationship for the Thermal Oxidation of Silicon, Journal of Applied Physics, 36 (1965) 3770-3778) to fit the relation between the extent of oxidation and annealing time, as shown by the dashed lines in FIG. 21A. FIG. 21A is a graph of XRD peak ratio for NiO(200)/Ni(111) as a function of annealing time in Ni—SiOₓ (x<2) system at 450, 550 and 600° C. in air. The dashed lines show the fitting curves using Deal-Grove oxidation model. The solid line shows a fitting curve using phenomenological exponential association model for the case of 600° C. annealing.

According to the Deal-Grove model, the reaction-limited oxidation increases linearly with time, while the diffusion-limited oxidation follows the square-root law, as described in Equation (5):

R_{NiO/Ni}=At+B\sqrt{t} (5)

Here R_{NiO/Ni} is the NiO(200)/Ni(111) XRD peak ratio, t is the annealing time, and A and B are the fitting parameters. This model fits the data at 450 and 550° C. very well. For both cases, the parameter A is negligibly small compared to B. Therefore, the oxidation processes at both temperatures are dominated by diffusion. On the other hand, the model does not fit the data at 600° C. very well, especially considering that the NiO/Ni ratio does not change between 80 and 120 min of annealing.

As a comparison, the solid black curve shows another fitting using an phenomenological exponential association model to capture the saturation after long-time annealing and the reaction limited linear oxidation as t˜0:

R_{NiO/Ni}=A(1−e^{-Bt}) (6)

This fitting works better at t>60 min, but the overall coefficient of determination (R²) is similar to the Deal-Grove model. As we will discuss later, this complication is likely due to the interfacial silicide phase transformation from Ni₃Si towards NiSi₂ at ≧600° C., which significantly slows down the oxidation rate.

In order to further investigate the effect of annealing temperature on the oxidation mechanism, we annealed the same Ni nanochain-SiOₓ (x<2) sample in air from 450 up to 675° C. At each temperature, the sample was annealed for 40 min. After each annealing, we performed XRD analysis to get the intensity ratio of NiO(200):Ni(111). Since the structural factors of NiO (200) (F_{NiO 200}) and Ni(111) (F_{Ni 111}) are related to the atomic scattering factors (f_{Ni}, f_{Ni}²⁺, f_{O}²⁻) by:

|F_{NiO 200}|²=|4f_{Ni}_{²⁺}+4f_{O}_{^{2−}}|² (7A)

|F_{Ni 111}|²=|4f_{Ni}|² (7B)

We can deconvolve these structural factors from the intensity ratios to obtain the oxide percentage in each scan.

FIG. 21B is a graph of XRD peak ratio for NiO(200)/Ni(111) as a function of annealing time. This graph shows the extent of oxidation as a function of annealing time for Ni—HSQ vs. Ni-TEOS cermet coatings. While TEOS is not as effective as HSQ in preventing oxidation, it still offers significantly better protection than Al₂O₃.

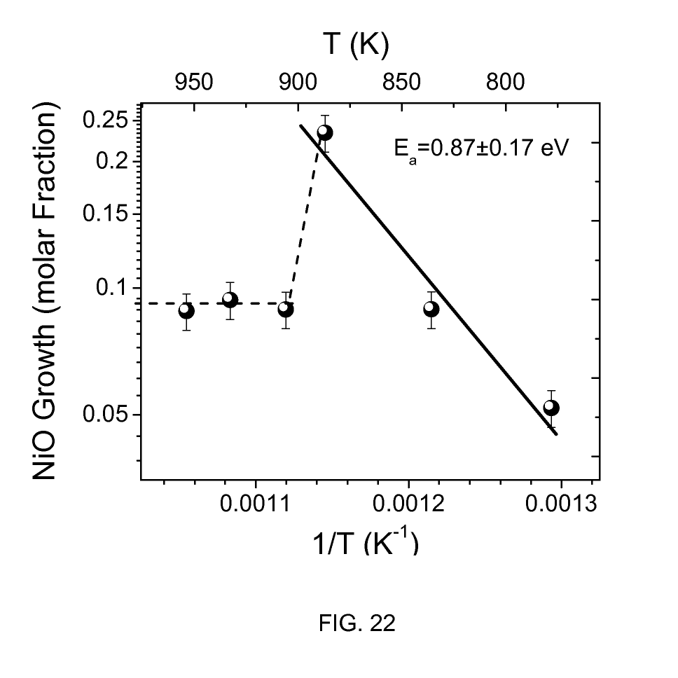

After obtaining the amount of oxide growth upon each annealing by subtracting the amount obtained in the previous step, we calculated the activation energy Eₐ of oxidation using Arrhenius plot, as shown in FIG. 22. FIG. 22 is a graph showing an Arrhenius plot of NiO growth in Ni—SiOₓ system from 450° C. to 675° C. (or 723K to 948K). An Arrhenius fitting is given in the temperature range of 450-600° C. with an oxidation activation energy of Eₐ=0.87±0.17 eV. In the temperature range of 450-600° C., an activation energy of Eₐ=0.87±0.17 eV is derived. This is comparable to the bonding energy of Ni—Si dimers (0.745 eV) (see for example, A. N. Andriotis, M. Menon, G. E. Froudakis, Z. Fthenakis, J. E. Lowther, “A tight-binding molecular dynamics study of NiₘSiₙ binary clusters”, Chem. Phys. Lett. 292 (1998) 487-492) as well as the activation energy for oxidation of silicides, implying the possibility of nickel silicide formation in the Ni—SiOₓ (x<2) system.

A remarkable feature in FIG. 22 is that the oxidation process deviates significantly from the Arrhenius plot at >600° C., indicating that other mechanisms start to play a role. As we will discuss in the next section, this phenomenon is likely due to the silicide phase transformation at >600° C., which leads to more Si-rich silicides that are more robust to oxidation. The oxidation kinetics is slowed down correspondingly.

### Bonding Analysis

To understand the interfacial chemistry between the Ni nanostructures and the matrix that leads to the anti-oxidation behavior in Ni—SiOₓ (x<2) system, we performed FTIR, XPS, and Raman spectroscopy analysis to probe the change in the chemical bonding upon annealing.

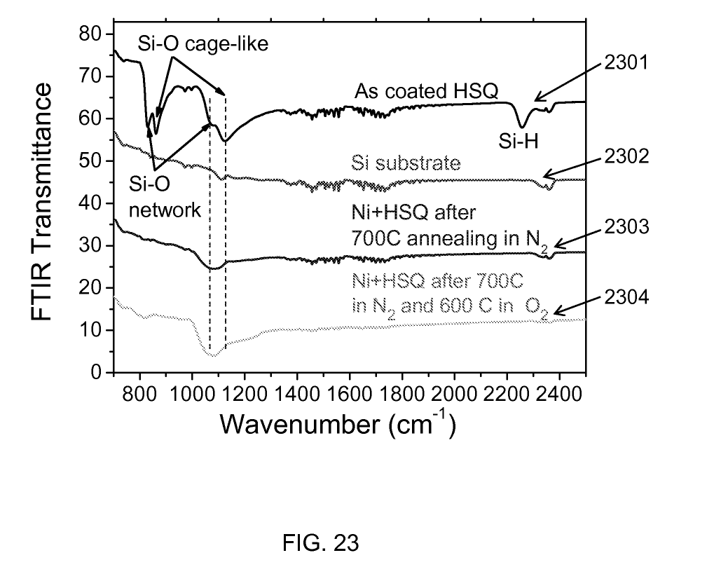

FIG. 23 is a graph showing FTIR spectra of (1) unannealed HSQ on Si substrate (2301); (2) Si substrate alone (2302) as a reference; (3) Ni nanochain-SiOₓ (x<2) on Si annealed in N₂ at 750° C. (2303); and (4) Ni nanochain-SiOₓ (x<2) on Si annealed in N₂ at 750° C. followed by 600° C. in air (2304). The associated vibration modes of the Si—O—Si network and cage structures are at 1070 cm⁻¹ and 1130 cm⁻¹, while the bending modes are at 830 and 880 cm⁻¹, respectively. See Alka A. Kumbhar, Sunil Kumar Singh, R. O. Dusane, “Enhancement of moisture resistance of spin-on low-k HSQ films by hot wire generated atomic hydrogen treatment”, Thin Solid Films, 501 (2006) 329-331 and Ta-Shan Chang, Ting-Chang Chang, Po-Tsun Liu, Tien-Shan Chang, Feng-Sheng Yeh, Integration issues for siloxane-based hydrogen silsesquioxane (HSQ) applied on TFT-LCDs, Thin Solid Films, 498 (2006) 70-74. When mixed with Ni and annealed at around 750° C., the intensity of vibration modes at 1070 cm⁻¹ and 1130 cm⁻¹ both decrease, with the cage structure decreasing more significantly. The bending modes cannot be observed any more after the annealing, consistent with the observation in Kumbhar et al. These results indicate the dissociation of the cage and network structures in the SiOₓ (x<2) matrix, which may have enabled the formation of new bonds with Ni to passivate the surface of Ni nanoparticles and prevent oxidation. During this process, the Ni nanostructures might form chemical bonds with Si, Si—O network and/or Si—O—Si cage in the SiOₓ (x<2) matrix, which help to resist oxidation at high temperatures in air. Similar mechanism may also apply to Ni—SiO₂ system, which also has Si—O network structures. Compared to stoichiometric SiO₂, SiOₓ (x<2) has excess Si that may also form silicide-like bonding with Ni, thereby adding more protection to the Ni nanostructures. To verify this assumption, XPS and micro-Raman analyses were applied to probe the Ni—Si bonds in the Ni—SiOₓ (x<2) system.

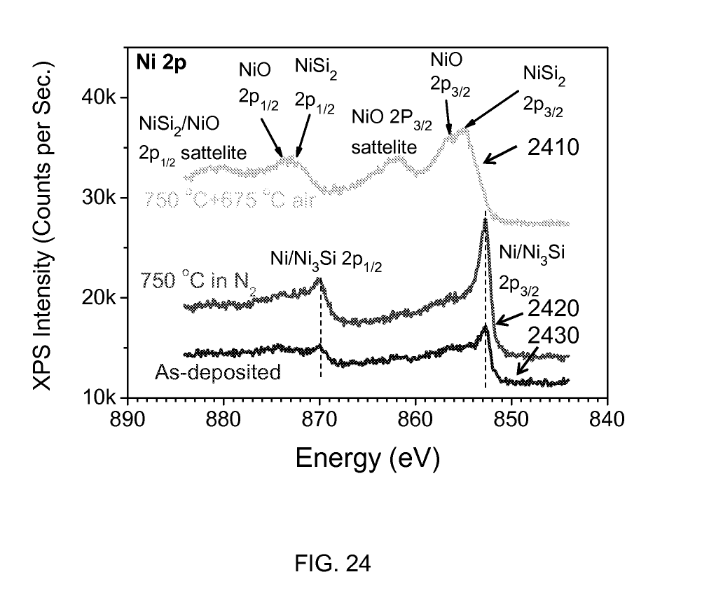

FIG. 24 is a graph showing X-ray photoelectron spectra (XPS) of (1) unannealed Ni—SiOₓ (x<2) on Si (2430); (2) Ni—SiOₓ (x<2) on Si annealed in N₂ at 750° C. (2420); and (3) Ni—SiOₓ (x<2) on Si annealed in N₂ at 750° C. and then in air up to 675° C. (2410). Silicide formation is clearly observed after annealing. The analysis shows that at the Ni—SiOₓ interface, the silicide is transformed from Ni₃Si to NiSi₂ as the temperature increases from 450° C. to 650° C., which offers more resistance to oxidation. This explains why the oxidation rate drops significantly at >600° C.

For the Ni 2p spectra, both unannealed Ni—SiOₓ (x<2) and Ni—SiOₓ (x<2) annealed in N₂ have two major peaks at almost the same positions, which correspond to Ni 2p_{3/2} (852.7 eV), Ni₃Si 2p_{3/2} (852.8 eV) and Ni₃Si 2p_{1/2} (870.0 eV). See for example Yu Cao, Lars Nyborg, Urban Jelvestam, XPS calibration study of thin-film nickel silicides, Surface and Interface Analysis, 41 (2009) 471-483 and M. A. Peck and M. A. Langell, “Comparison of nanoscaled and bulk NiO structural and environmental characteristics by XRD, XAFS, and XPS”, Chemistry of Materials, 24 (2012) 4483-4490. Selected area electron diffraction studies also confirmed the formation of Ni₃Si in the sample annealed in N₂ at 750° C. For the sample annealed in N₂ at 750° C. followed by annealing in air at 675° C., NiSi₂ 2p_{3/2} (854.6 eV), 2p_{1/2} (871.8 eV) and its satellite peak (880 eV) are clearly observed, along with the NiO 2P_{3/2} and its satellite peaks at 855 and 861 eV, respectively. From these observations, it can be concluded that Ni-rich Ni silicides (Ni₃Si) were formed on the surfaces of Ni nanoparticles through the process of mixing and annealing in N₂; after being annealed in air, Ni₃Si reacted with oxygen and transformed into a Si-rich silicide phase (i.e. NiSi₂) and NiO. For instance, a possible chemical reaction like Equation (8) could have occurred during this oxidation process.

3Ni₃Si+5O₂→8NiO+NiSi₂+SiO₂ (8)

NiSi₂ is more resistant to oxidation than Ni₃Si since it is more Si-rich. It has been shown that NiSi₂ can sustain an accelerated oxidation test at 850° C. in steam for 20 min without any measurable oxidation. Therefore, after the formation of NiSi₂ at ≧600° C., the oxidation kinetics is significantly slowed down. This silicide phase transformation explains the sudden decrease in oxidation rate at ≧600° C. shown in FIG. 22, as well as the saturation of oxidation after annealing for >80 min at 600° C. in FIG. 21.

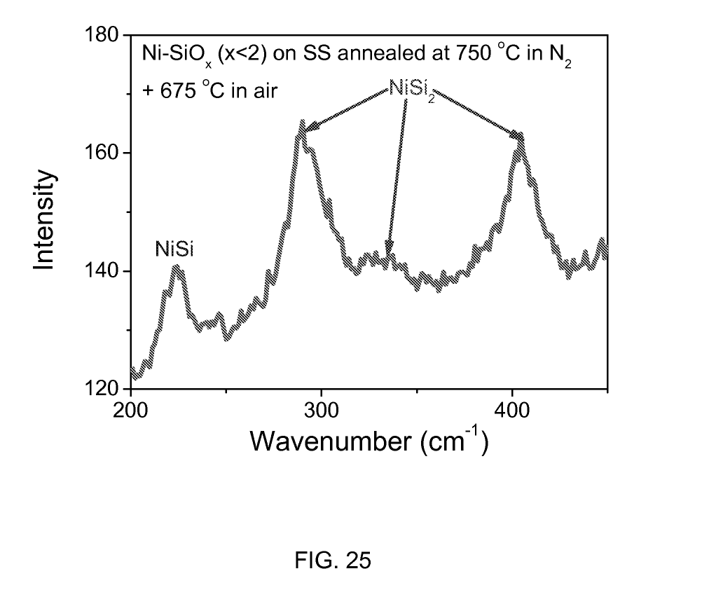

The Raman spectroscopy of the Ni—SiOₓ sample annealed at 750° C. in N₂ followed by 675° C. in air further confirms the silicide formation. FIG. 25 is a graph showing a Raman spectrum of Ni—SiOₓ (x<2) on stainless steel substrate annealed at 750° C. in N₂ followed by 675° C. in air. As shown in FIG. 25, NiSi and NiSi₂ Raman peaks were found at 224, 292, 332 and 404 cm⁻¹, which are largely consistent with peaks at 216, 288, 320, and 397 cm⁻¹ observed in previous research. See S. K. Donthu, D. Z. Chi, S. Tripathy, A. S. W. Wong and S. J. Chua, Micro-Raman spectroscopic investigation of NiSi films formed on BF⁺₂-, B⁺- and non-implanted (100) Si substrates, Appl. Phys. A 79 (2004) 637-642 and F. F. Zhao, S. Y. Chen, Z. X. Shen, X. S. Gao, J. Z. Zheng, A. K. See, and L. H. Chan, “Applications of micro-Raman spectroscopy in silicide characterization for Si device fabrication”, J. Vac. Sci. Technol. B 21 (2003) 862-867. We notice that the peaks generally shift to larger wavenumbers compared to literature, which may indicate compressive strain in these silicide interfacial layers. Due to equipment cut-off at <190 cm⁻¹, we are unable to observe Ni₃Si and Ni₂Si Raman peaks at <190 cm⁻¹, as described by P. S. Lee, D. Mangelinck, K. L. Pey, Z. X. Shen, J. Ding, T. Osipowicz, and A. See, “Micro-Raman Spectroscopy Investigation of Nickel Silicides and Nickel (Platinum) Silicides”, Electrochem. Solid State Lett. 3 (2000) 153-155. Overall, the Raman and XPS data indicate that multiple silicide phases, including Ni₃Si, NiSi, and NiSi₂, are formed at the Ni/matrix interface to protect the Ni nanostructures from oxidation.

### Optical Properties at Room Temperature and High Temperature

To characterize the optical properties of our anti-oxidation cermet coatings, Ni nanochain-SiOₓ was spin-coated on 316 stainless steel substrates (SS). The plates were cut into 2×2 cm² square pieces and cleaned with ethanol. The coating procedure has been described hereinabove. The viscosity of the precursor is fine tuned to obtain more uniform distribution of the Ni nanoparticles upon coating.

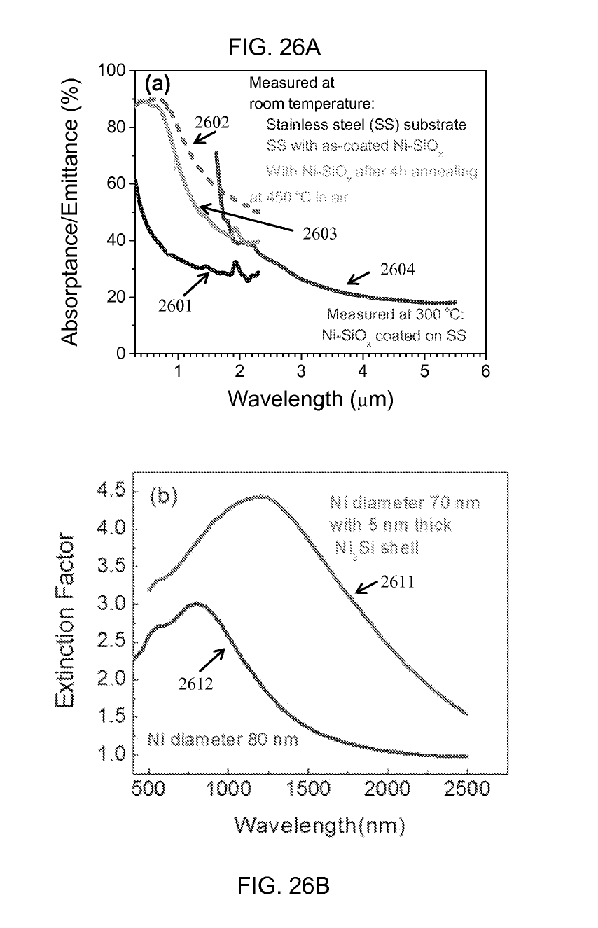

FIG. 26A is a graph showing absorptance/emittance spectra measured at room temperature (curves 2601-2603) and 300° C. (curve 2604). Curve 2601: stainless steel (SS) substrate alone; Curve 2602: as-coated Ni nanochain-SiOₓ on SS substrate before being annealed in air; Curve 2603: Ni nanochain-SiOₓ on SS substrate annealed in air at 450° C. for 4 h; and Curve 2604: thermal emittance measured at 300° C. for Ni nanochain-SiOₓ on SS substrate annealed in air at 450° C. for 4 h. The data show a significant red-shift in the absorptance/emittance edge from λ˜1.0 to λ˜1.8 μm compared to room temperature, covering almost the entire solar spectrum regime.

The reflectance spectra of three samples (2601. 2602, 2603) have been measured at room temperature using the UV-VIS-IR spectrometer. Since the transmittance through the substrate is 0 (zero), the absorptance/emittance at each wavelength can be simply derived as one minus reflectance. As shown in curve 1, the absorptance of the SS substrate is only around 30-40% in the visible regime. It is expected that the selective solar thermal absorber will significantly increase the absorptance in the visible regime while maintaining a low emittance in the infrared regime. As expected, the Ni nanochain-SiOₓ cermet coatings increase the absorptance in the UV, visible, and near infrared regime to ˜90% (λ=300-850 nm), as shown in curves 2602 and 2603. Furthermore, we find that after 4 h annealing at 450° C. in air (curve 2603), an even lower emittance in the infrared regime is achieved without sacrificing the high absorptance in the visible regime compared to the unannealed one (curve 2602). This result directly confirms the effectiveness of the anti-oxidation Ni nanochain-SiOₓ selective solar absorber coating.

At room temperature, the absorptance/emittance is >90% in the visible light regime, and it starts to drop at λ>1 μm. While this feature is consistent with our optical simulation using room-temperature dielectric functions of Ni and HSQ, ideally one would like to redshift this absorptance/emittance edge to longer wavelengths at λ>1.5 μm so that nearly the entire solar spectrum is absorbed while the emittance in MIR regime remains low. Interestingly and surprisingly, at 300° C. the direct thermal emittance measurement of the same sample in reference to a blackbody standard shows that the absorptance/emittance edge is drastically redshifted from 0.8 μm (room temperature) to ˜1.8 μm. Therefore, the same coating actually demonstrates significantly better optical performance at high temperatures than room temperature, indicating that the temperature-dependent dielectric functions of this nanostructured metal/glass system play a critical role. From the data measured at 300° C., the solar absorptance is estimated to be ˜90% while the emittance is ˜20%. Due to the fact that emittance is too low to measure directly at <200° C., we have not been able to observe a continuous change in emittance spectra vs. temperature.

FIG. 26B is a graph of the theoretically calculated optical response of Ni nanochain-SiOₓ (x<2) with (2611) and without (2612) Ni₃Si shells at room temperature using the dielectric functions of Ni and HSQ at room temperature and the finite element method described in Wang, et al. The extinction factor refers to the extinction cross-section divided by the cross-section of the Ni nanoparticles.

The theoretically modelled absorptance/emittance edge at λ˜1.0 μm is consistent with the room temperature experimental result in FIG. 26A, curves 2602 and 2603.

The optical performance at 300° C. is characterized by directly measuring the emission spectra from the samples and normalizing the spectra to that of the black body reference. Note that at this temperature the emittance at λ<1.5 μm is too weak to measure directly. Compared to the result at room temperature, the optical performance at 300° C. is even better since the absorptance/emittance edge is notably red-shifted from λ=1.0 μm (room temperature) to ˜1.8 μm, covering almost the entire solar spectral regime. The emittance at λ>3 μm, which is the major thermal emittance spectral regime at 300° C., is only 20%. Therefore, the coating shows excellent spectral performance at high-temperature operation. The redshift in absorptance/emittance edge at 300° C. is likely due to the change in the refractive index of the cermet materials at high temperatures, considering that the plasmonic response is sensitive to the change in dielectric functions. See for example H. Raether, Surface plasmon on smooth and rough surface and gratings (Springer-Verlag, Berlin, 1986). This result suggests that dielectric functions of Ni and the SiOₓ (x<2) matrix at high temperatures need to be investigated in order to further optimize the performance of the Ni-nanochain cermet coating.

Anti-oxidation Ni nanochain-SiOₓ (x<2) selective solar absorber coatings have been fabricated by a vacuum-free, low-cost solution-chemical method for solar thermal applications. Compared to Ni—Al₂O₃ system which was readily oxidized at 450° C. in air, the Ni nanochain-SiOₓ (x<2) system exhibits a strong anti-oxidation behavior up to 600° C. in air. There are two factors contributing to the anti-oxidation behavior: (1) the dissociation of Si—O cage-like structures and Si—O networks in the SiOₓ (x<2) matrix at high temperatures enables the formation of new bonds at the Ni/SiOₓ interface to passivate the surface of Ni nanoparticles and prevent oxidation; (2) the excess Si in the SiOₓ (x<2) matrices reacts with Ni nanostructures to form silicides at the interface, which further improves the anti-oxidation properties. This anti-oxidation Ni nanochain-SiOₓ coating also demonstrates excellent high-temperature optical performance, with a high solar absorptance of 90% and a low thermal emittance of 20% at 300° C. These results represent a step forwards towards atmospherically stable, high temperature, high-performance solar selective absorber coatings processed by low-cost solution chemical methods for future generations of CSP systems.

We have investigated a high temperature pre-annealing technique to directly form NiSi₂ bonding at the surface of Ni nanochains to optimize the antioxidation behavior.

We investigated a high-temperature “preannealing” process at >650° C. to directly obtain NiSi₂ at the interface. Since the interfacial structure is already stabilized by NiSi₂ at >650° C., no further oxidation will occur at the operation temperature of 600° C. Since the concept of silicide-stabilized interfaces against oxidation can be applied to other metal nanostructures, we further contemplate alternative systems such as Cr or Co to further optimize the antioxidation properties. CrSi₂ and CoSi₂ are known to resist oxidation under an accelerated test in steam up to 1000° C. for 20 min. (See for example Strydom W J, Lombaard J C, and Pretorius R, “THERMAL OXIDATION OF THE SILICIDES CoSi₂, CrSi₂, NiSi₂, PtSi, TiSi₂, AND ZrSi₂,” Thin Solid Films 131, 215-31 (1985) (hereinafter “Strydom 1985”).

CrSi₂ and CoSi₂ are expected to offer even better antioxidation properties than NiSi₂.

In terms of optical performance, we found that the temperature-dependent optical properties cannot be neglected in this material system. One should design and optimize the performance at high temperatures.

### High-Temperature Testing of Cermet Optical Properties

Our recent results indicate that the high-temperature optical properties of Ni nanochain-SiOₓ cermets are dramatically different from those at room temperature.

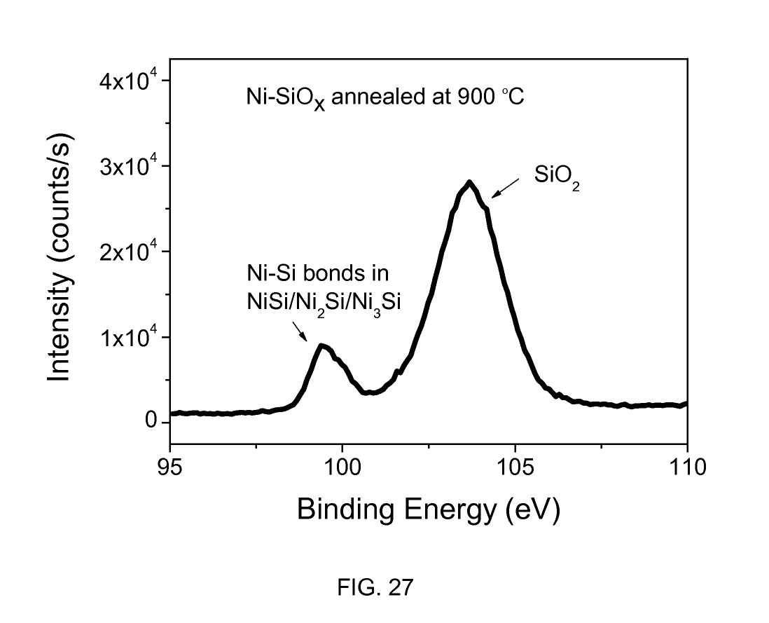

FIG. 27 is a graph showing the X-ray photoelectron (XPS) spectrum of Ni nanochain-HSQ annealed at 900° C. in N₂. FIG. 27 shows that Ni—SiOₓ annealed at 900° C. in N₂ has a peak around 99.4 eV corresponding to Ni—Si binding energy in NiSi/Ni₂Si/Ni₃Si, which hasn't been found in previous 750° C. samples.

Extended thermal cycling test has been conducted on the 450° C.-4-h-in-air sample. We annealed the same sample in air at 580° C. for 1 h, and then cooled it down. This cycle is repeated 12 times.

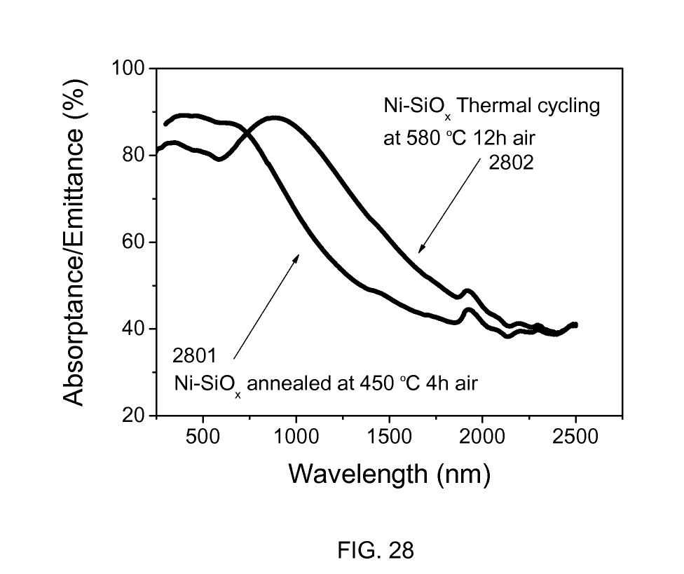

FIG. 28 is a graph showing the reflectance spectra measured at room temperature of Ni nanochain-HSQ on SS substrate after annealing at 450° C. for 4 h in air (2801) and after thermal cycling at 580° C. for 12 h in air (2802). The measured absorptance/emittance at room temperature is shown in FIG. 28. After thermal cycling, the sample shows a desirable red-shift from before cycling. The edge of the curve after test is around 1.1 μm while before test is around 0.8 μm. Even if the absorptance/emittance decreases slightly in the visible regime, it is still above 80%, which is good for most of the solar thermal absorbers.

We used the selected area electron diffraction (SAED) patterns from transmission electron microscopy (TEM) to identify unknown phases.

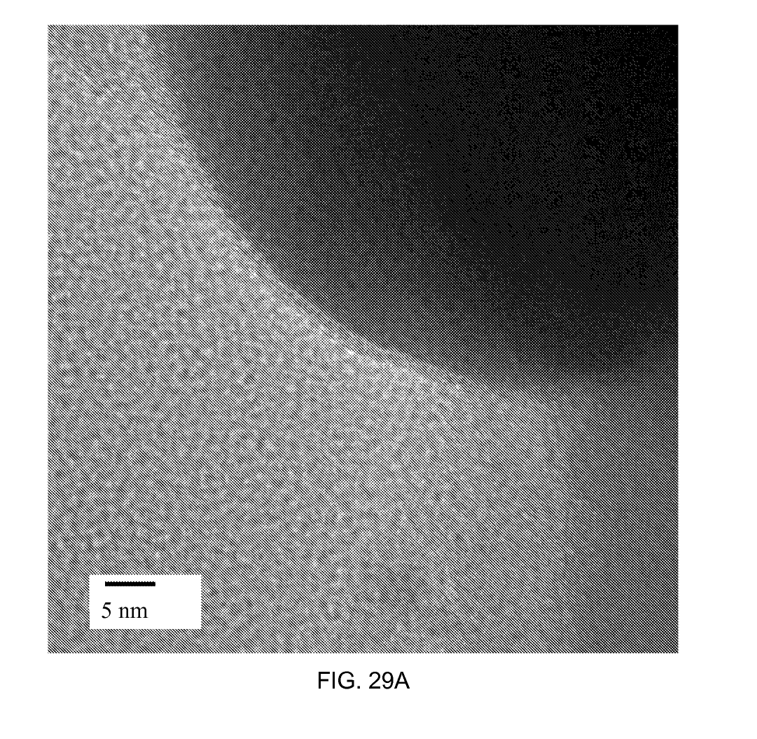

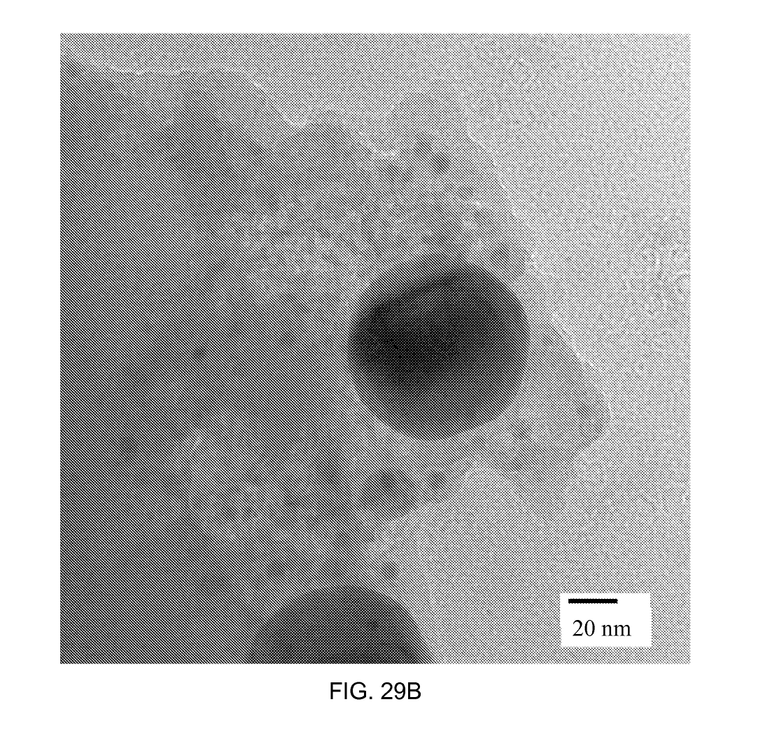

FIG. 29A is an image of a core-shell structure of Ni nanochain-HSQ annealed at 900° C. in N₂. FIG. 29B is a TEM image of a Ni nanochain-HSQ annealed at 900° C. in N₂.

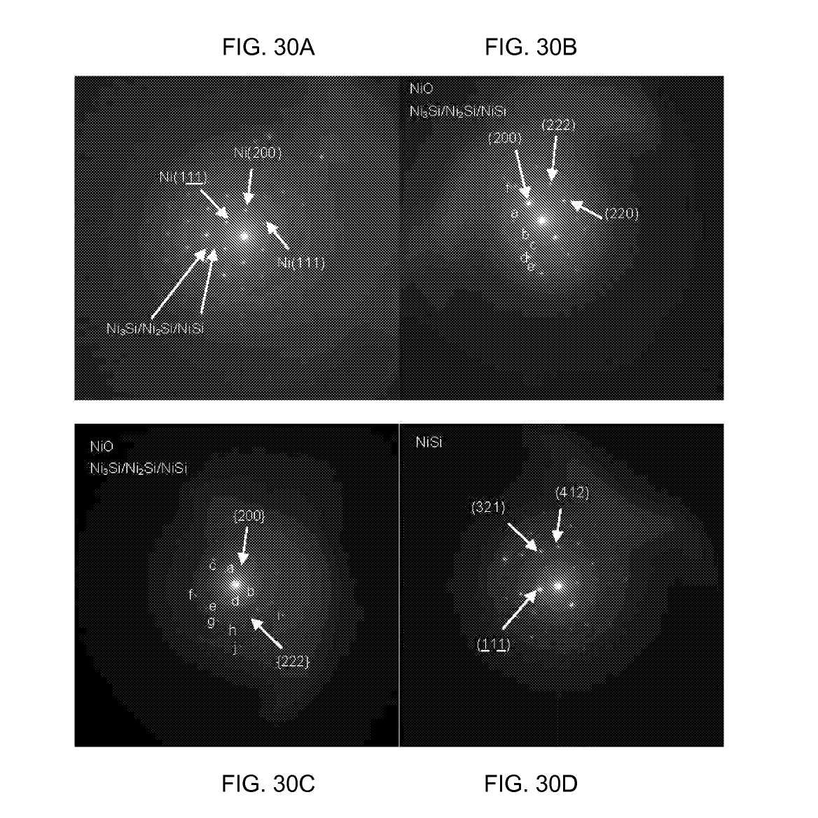

FIG. 30A, FIG. 30B, FIG. 30C, and FIG. 30D are TEM selected area electron diffraction (SAED) patterns of Ni nanochain-HSQ annealed at 900° C. in N₂.

We have identified different orientations of Ni, NiO and NiSi/Ni₂Si/Ni₃Si from the SAED dots as expected. Note that since the electron beam can only penetrate ˜50 nm of the material, these data are mostly from the region near the surface of the particle. Therefore, the formation of silicides near the Ni nanochain/SiOₓ interface is again confirmed.

We have systematically studied the interfacial Ni silicide formation in conjunction with temperature-dependent optical response by measuring reflectance spectra vs. temperature. This way, we can derive the emittance between room temperature and 600° C. and obtain a systematic understanding of the high temperature optical properties. Our simulations also show that the formation of silicide at the interface is expected to have a notable beneficial impact on the optical response spectra. Cr and Co systems are believed to offer even better antioxidation behavior than the Ni silicide system. It is believed that microemulsion fabrication recipes for Ni nanochain structures will allow the coating process to be scaled to large area at low costs.

### DEFINITIONS

Unless otherwise explicitly recited herein, any reference to an electronic signal or an electromagnetic signal (or their equivalents) is to be understood as referring to a non-volatile electronic signal or a non-volatile electromagnetic signal.

Recording the results from an operation or data acquisition, such as for example, recording results at a particular frequency or wavelength, is understood to mean and is defined herein as writing output data in a non-transitory manner to a storage element, to a machine-readable storage medium, or to a storage device.

### Theoretical Discussion

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

### INCORPORATION BY REFERENCE

Any patent, patent application, patent application publication, journal article, book, published paper, or other publicly available material identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A system for spectrally selective radiation absorption, comprising:
a matrix comprising uniformly dispersed metal nanostructures having plasmonic spectrally selective radiation absorption properties, such that the matrix reflects a majority of light incident thereupon for wavelengths greater than a cutoff wavelength and absorbs a majority of light incident thereupon for wavelengths smaller than the cutoff wavelength.

2. The system of claim 1, wherein the majority of light incident upon the metal nanostructures for wavelengths smaller than the cutoff wavelength is absorbed by surface plasmon resonance in the metal nanoparticles.

3. The system of claim 2, wherein each of the nanostructures comprises at least two metal nanoparticles, the at least two metal nanoparticles having a broader absorption spectrum than that of a single metal nanoparticle.

4. The system of claim 3, wherein the nanostructures comprise nanochains of metal nanoparticles.

5. The system of claim 2, wherein the metal nanoparticles comprise a ferromagnetic metal.

6. The system of claim 5, wherein the metal nanoparticles comprise Ni and the matrix comprises a selected one of SiOₓ (x<2) and SiO₂.

7. The system of claim 1, wherein the spectrally selective radiation absorption properties of the metal nanostructures in the matrix are insensitive to the thickness of the matrix.

8. The system of claim 1, further comprising a thermal reservoir.

9. The system of claim 1, wherein the cutoff wavelength is located between the peak of the solar radiation spectrum and the peak of the blackbody radiation spectrum of the thermal reservoir.

10. The system of claim 1, wherein the matrix is present in the form of a coating.

11. The system of claim 10, wherein the coating has a thickness in the range from the diameter of the metal nanoparticles to 10 μm.

12. The system of claim 1, further comprising a heat source and a photovoltaic element.

13. The system of claim 12, wherein the cutoff wavelength is located between the peak of the photovoltaic element absorption spectrum and the peak of the black body radiation spectrum of the heat source.

14. The system of claim 1, wherein the matrix further comprises a material that forms chemical bonds with the metal nanoparticles such that the oxidation rate of the metal nanoparticles is reduced.

15. The system of claim 14, wherein the material comprises at least one of Si, a Si—O network, Ge, a Ge—O network, a Si—C—O network, a Ge—C—O network, a Si—Ge—C—O network, or a combination thereof.

16. The system of claim 1, wherein the metal nanostructures comprise at least one metal nanoparticle containing a selected one of Ni, Cr, and Co.

17. The system of claim 16, wherein the at least one metal nanoparticle containing a selected one of Ni, Cr, and Co comprises a silicide.

18. A method of manufacturing a spectrally selective absorber, comprising the steps of:
forming nanostructures, each nanostructure comprising at least one metal nanoparticle;
uniformly dispersing the nanostructures in a matrix material to form a liquid matrix;
applying the liquid matrix to a surface;
drying the liquid matrix; and
annealing the matrix.

19. The method of claim 18, wherein the matrix material forms chemical bonds with the metal nanoparticles such that the oxidation rate of the metal nanoparticles is reduced.

20. The method of claim 19, wherein the step of applying the liquid matrix is performed by solution-chemical processes.

21. The method of claim 20, wherein the solution-chemical processes comprise one or more of spin coating, drip coating, dip coating, spray coating, roller coating, and knife-over-edge coating.

22. The method of claim 20, wherein the solution-chemical processes comprise spin coating at increasing spin rates comprising at least a lower spin rate and a higher spin rate.

23. The method of claim 18, wherein the step of annealing is performed at increasing temperatures comprising at least a lower temperature and a higher temperature.

24. The method of claim 18, wherein the step of forming nanostructures is performed by solution-chemical processes.

25. The method of claim 18, wherein the at least one metal nanoparticle comprises a selected one of Ni, Cr, and Co.

26. The method of claim 25, wherein the at least one metal nanoparticle comprising a selected one of Ni, Cr, and Co comprises a silicide.

27. The method of claim 19, wherein the matrix material comprises at least one of SiOₓ (x<2), SiO₂, a precursor for SiOₓ (x<2), and a precursor for SiO₂.

28. The method of claim 19, wherein the matrix material comprises at least one of Si, a Si—O network, Ge, a Ge—O network, a Si—C—O network, a Ge—C—O network, a Si—Ge—C—O network, or a combination thereof.

29. The method of claim 19, wherein the surface is steel.
